(19) United States
(12) Patent Application Publication
(10) Pub. No.: US 2026/0096306 A1
(43) Pub. Date: Apr. 2, 2026

(54) DISPLAY DEVICE, ELECTRONIC DEVICE AND METHOD FOR FABRICATING THE SAME

(71) Applicant: SAMSUNG DISPLAY CO., LTD., YONGIN-SI (KR)

(72) Inventors: Han Bit KIM, Yongin-si (KR); Mee Jae KANG, Yongin-si (KR); Sang Hyun YUN, Yongin-si (KR); Do Kyeong LEE, Yongin-si (KR); Ki Seok CHOI, Yongin-si (KR); Sang Gun CHOI, Yongin-si (KR)

(21) Appl. No.: 19/185,447

(22) Filed: Apr. 22, 2025

(30) Foreign Application Priority Data
Sep. 30, 2024 (KR) 10-2024-0132441

(51) Int. Cl. H10K 59/124; H10D 86/01; H10D 86/40; H10D 86/60; H10H 29/01; H10H 29/39; H10H 29/41; H10K 59/12; H10K 59/123

(52) U.S. Cl. CPC H10K 59/124; H10D 86/021; H10D 86/441; H10D 86/451; H10D 86/60; H10H 29/012; H10H 29/39; H10H 29/41; H10K 59/1201; H10K 59/123

(57) ABSTRACT

A display device including: a substrate; a light emitting element layer on the substrate; a first conductive layer between the substrate and the light emitting element layer; a first insulating film on the first conductive layer and having a first contact hole; a second insulating film between the first insulating film and the light emitting element layer and having a second contact hole overlapping the first contact hole; a second conductive layer on the first insulating film and connected to the first conductive layer through the first contact hole; a first filler in the first contact hole; and a third insulating film within the first contact hole and positioned between the second conductive layer and the first filler.

### CROSS-REFERENCE TO RELATED APPLICATION

This application claims priority under 35 U.S.C. 119 to Korean Patent Application No. 10-2024-0132441 filed on Sep. 30, 2024 in the Korean Intellectual Property Office, the disclosure of which is incorporated by reference herein in its entirety.

### 1. TECHNICAL FIELD

The present disclosure relates to a display device, and more particularly, to a display device and an electronic device capable of easily achieving high resolution, as well as a method for fabricating the same.

### 2. DESCRIPTION OF THE RELATED ART

An organic light-emitting diode (OLED) display is self-emissive and does not require a separate light source, unlike a liquid crystal display, allowing for reduced thickness and weight. Additionally, OLED displays have gained attention as next-generation displays for televisions, monitors, and portable electronic devices due to their advantages, including low power consumption, high luminance, and fast response speed.

### SUMMARY

Aspects of the present disclosure provide a display device that easily implements a high resolution and a method for fabricating the same.

According to an embodiment of the present disclosure, there is provided a display device including: a substrate; a light emitting element layer on the substrate; a first conductive layer between the substrate and the light emitting element layer; a first insulating film on the first conductive layer and having a first contact hole; a second insulating film between the first insulating film and the light emitting element layer and having a second contact hole overlapping the first contact hole; a second conductive layer on the first insulating film and connected to the first conductive layer through the first contact hole; a first filler in the first contact hole; and a third insulating film within the first contact hole and positioned between the second conductive layer and the first filler.

According to an embodiment of the present disclosure, there is provided a method for fabricating a display device, including: depositing a first conductive layer on a substrate; forming a first insulating film on the first conductive layer; planarizing the first insulating film; creating a first contact hole through the first insulating film to expose the first conductive layer; depositing a second conductive layer on the first insulating film, connected to the first conductive layer through the first contact hole; forming a second insulating film in the first contact hole and on the first insulating film and the second conductive layer; depositing an organic film in the first contact hole and on the second insulating film; removing the organic film from the second insulating film without a mask to form a filler within the first contact hole; exposing the second conductive layer; creating a second contact hole overlapping the first contact hole on the second conductive layer; depositing a third conductive layer, connected to the second conductive layer through the second contact hole; and forming a light emitting element layer on the third conductive layer.

According to an embodiment of the present disclosure, there is provided a method for fabricating a display device, including: depositing a first conductive layer on a substrate; forming a first insulating film on the first conductive layer; creating a first contact hole through the first insulating film to expose the first conductive layer; depositing a second conductive layer on the first insulating film, connected to the first conductive layer through the first contact hole; forming a second insulating film in the first contact hole and on the first insulating film and the second conductive layer; depositing an organic film in the first contact hole and on the second insulating film; removing the organic film in a region overlapping the first contact hole to form a filler on the second insulating film within the first contact hole, and forming an auxiliary planarization film on the second insulating film outside the first contact hole; exposing the second conductive layer; creating a second contact hole overlapping the first contact hole on the second conductive layer; depositing a third conductive layer, connected to the second conductive layer through the second contact hole; and forming a light emitting element layer on the third conductive layer.

According to an embodiment of the present disclosure, there is provided an electronic device including: a display device including a screen; wherein the display device includes: a substrate; a light emitting element layer on the substrate; a first conductive layer between the substrate and the light emitting element layer; a first insulating film on the first conductive layer and having a first contact hole; a second insulating film between the first insulating film and the light emitting element layer and having a second contact hole overlapping the first contact hole; a second conductive layer on the first insulating film and connected to the first conductive layer through the first contact hole; a first filler in the first contact hole; and a third insulating film in the first contact hole and positioned between the second conductive layer and the first filler.

According to one embodiment of the display device, a filler may be disposed between vertically adjacent contact holes to minimize the height difference between the interior and exterior of the contact hole. As a result, even when the contact holes are vertically aligned within the display panel, issues such as disconnection of the driving voltage line or poor connection of conductive layers can be prevented. Accordingly, the contact holes can be arranged in the vertical direction without connectivity issues between conductive layers, enabling a reduction in pixel size. Furthermore, even as the number of contact holes increases, high-resolution implementation remains feasible.

The effects of the present disclosure are not limited to the above-described effects and other effects which are not described herein will become apparent to those skilled in the art from the following description.

### BRIEF DESCRIPTION OF THE DRAWINGS

The above and other aspects and features of the present disclosure will become more apparent by describing in detail example embodiments thereof with reference to the attached drawings, in which:

FIG. 1 is a plan view schematically illustrating a part of a display device according to one embodiment;

FIG. 2 is a diagram showing a circuit configuration of a pixel of a display device;

FIG. 3 is a plan view of an array structure of a pixel according to one embodiment;

FIG. 4 is a plan view selectively showing a first pattern layer, a second pattern layer, and a third pattern layer among the components of FIG. 3;

FIG. 5 is a diagram selectively showing the first pattern layer, a fourth pattern layer, a fifth pattern layer, and a sixth pattern layer among the components of FIG. 3;

FIG. 6 is a cross-sectional view taken along line I-I′ of FIG. 3;

FIG. 7 is a cross-sectional view of a display device according to another embodiment;

FIG. 8 is a cross-sectional view of a display device according to another embodiment;

FIG. 9 is a cross-sectional view of a display device according to another embodiment;

FIGS. 10, 11, 12, 13, 14, 15, 16, 17, 18, 19, 20, 21, and 22 are process cross-sectional views illustrating a method for fabricating a display device according to one embodiment;

FIGS. 23, 24, 25, 26, 27, 28, 29, 30, 31, and 32 are process cross-sectional views illustrating a method for fabricating a display device according to another embodiment;

FIG. 33 is a perspective view illustrating a head mounted display according to one embodiment;

FIG. 34 is an exploded perspective view illustrating an example of the head mounted display of FIG. 33; and

FIG. 35 is a perspective view illustrating a head mounted display according to one embodiment.

FIG. 36 is a block diagram of an electronic device according to one embodiment.

FIGS. 37, 38 and 39 are schematic diagrams of electronic devices according to various embodiments.

### DETAILED DESCRIPTION OF THE EMBODIMENTS

The present invention will now be described more fully hereinafter with reference to the accompanying drawings, in which example embodiments of the invention are shown. This invention may, however, be embodied in different forms and should not be construed as limited to the embodiments set forth herein.

It will be understood that when a layer is referred to as being “on” another layer or substrate, it can be directly on the other layer or substrate, or intervening layers may also be present. The same reference numbers indicate the same components throughout the specification. In the attached figures, the thickness of layers and regions may be exaggerated for clarity.

Although the terms “first”, “second”, etc. may be used herein to describe various elements, these elements, should not be limited by these terms. These terms may be used to distinguish one element from another element. Thus, a first element discussed below may be termed a second element. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various embodiments of the present disclosure may be combined partially or totally. As will be clearly appreciated by those skilled in the art, technically various interactions and operations are possible. Various embodiments can be practiced individually or in combination.

This invention relates to a high-resolution display device, specifically an OLED display, and its fabrication method. The device includes multiple conductive and insulating layers structured to improve connectivity and minimize defects, particularly in contact holes that connect vertical layers. A key aspect of the design is the use of a filler material within these contact holes to reduce height differences between adjacent layers, thereby preventing issues like disconnection in the driving voltage line. This enables a more compact pixel design, facilitating higher resolution without compromising structural integrity. The display panel is suitable for various electronic devices, including smartphones, tablets, and televisions.

The fabrication method involves forming a sequence of conductive layers, insulating films, and organic fillers to ensure proper alignment and electrical connectivity between vertically stacked contact holes. By carefully managing the formation of contact holes and utilizing an organic filler, the method improves manufacturing reliability and reduces performance issues such as poor conductive layer connections. Additionally, the structure supports a more efficient pixel circuit design, allowing precise control over light-emitting elements. The approach enhances the overall resolution and efficiency of the display device, making it more suitable for high-end applications like head-mounted displays and other advanced screen technologies.

Hereinafter, embodiments will be described in detail with reference to the accompanying drawings.

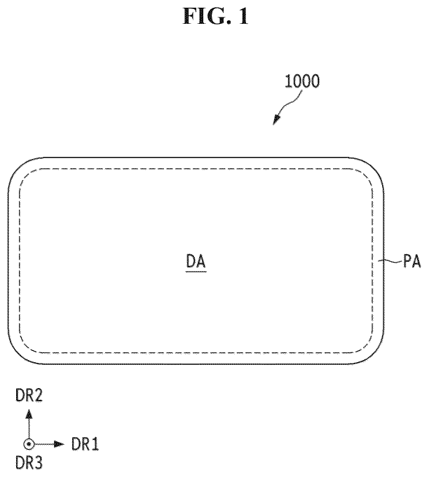

FIG. 1 is a plan view schematically illustrating a part of a display device according to one embodiment.

The display device according to one embodiment of the present disclosure may include a display panel 1000 as illustrated in FIG. 1. Any display device including the display panel 1000 may be used as the display device. For example, the display device may be a smart phone, a tablet, a laptop, a television, or a billboard. The display panel 1000 may include a display area DA and a peripheral area PA (or non-display area) outside the display area DA.

The display area DA may be a portion for displaying an image, and a plurality of pixels may be disposed in the display area DA. When viewed in a direction (e.g., a third direction DR3) substantially perpendicular to the display panel 1000, the display area DA may have various shapes, such as an elliptical shape, a polygonal shape, or a shape of a specific figure. FIG. 1 illustrates that the display area DA has a substantially rectangular shape with rounded corners. The display panel 1000 included in the display device according to the present embodiment has the display area DA with a shape where the length in a first direction DR1, corresponding to the horizontal direction, is greater than the length in a second direction DR2, corresponding to the vertical direction. This shape of the display area DA indicates that the substrate included in the display panel 1000 also has a display area of the same shape. Various driving circuits may be positioned in the peripheral area PA of the display panel 1000.

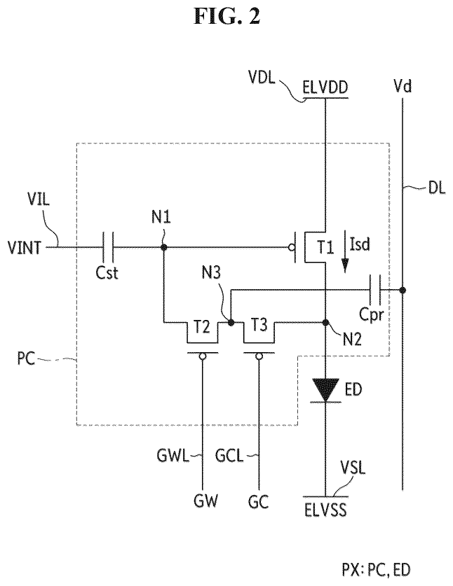

FIG. 2 is a diagram showing a circuit configuration of a pixel of a display device. For example, FIG. 2 may be an equivalent circuit of a pixel disposed in the display area DA of the display panel 1000 illustrated in FIG. 1.

A pixel PX may be connected to a first gate line GWL, a second gate line GCL, a data line DL, a driving voltage line VDL, a common voltage line VSL, and an initialization voltage line VIL.

The pixel PX may include a pixel circuit PC and a light emitting element ED connected to the pixel circuit PC. The pixel circuit PC may include a first transistor T1, a second transistor T2, a third transistor T3, a first capacitor Cst, and a second capacitor Cpr.

The first transistor T1 may include a gate electrode, a source electrode, and a drain electrode. The first transistor T1 may control a source-drain current Isd (hereinafter, a driving current) based on the data voltage Vd applied to its gate electrode. The driving current Isd flowing through the channel region of the first transistor T1 may be proportional to the square of the difference between a threshold voltage Vth and a source-gate voltage Vsg of the first transistor T1, expressed as: (Isd=k×(Vsg−Vth)²). Here, k is a proportional coefficient determined by the structure and physical characteristics of the first transistor T1, Vsg is a source-gate voltage of the first transistor T1, and Vth is a threshold voltage of the first transistor T1. The gate electrode of the first transistor T1 may be connected to a first node N1, the source electrode of the first transistor T1 may be connected to the driving voltage line VDL, and the drain electrode of the first transistor T1 may be connected to a second node N2. Here, the driving voltage line VDL may transmit a driving voltage ELVDD to the source electrode of the first transistor T1.

The light emitting element ED may emit light by receiving the driving current Isd. The emission amount or the luminance of the light emitting element ED may be proportional to the magnitude of the driving current Isd.

The light emitting element ED may be an organic light emitting diode including a first electrode (e.g., an anode electrode), a second electrode (e.g., a cathode electrode), and an organic light emitting layer disposed between the first electrode and the second electrode. As another example, the light emitting element ED may be an inorganic light emitting element including a first electrode, a second electrode, and an inorganic semiconductor disposed between the first electrode and the second electrode. As still another example, the light emitting element ED may be a quantum dot light emitting element including a first electrode, a second electrode, and a quantum dot light emitting layer disposed between the first electrode and the second electrode. As still another example, the light emitting element ED may be a micro light emitting diode.

The first electrode of the light emitting element ED may be electrically connected to the second node N2. The first electrode of the light emitting element ED may be connected to the drain electrode of the first transistor T1 and the drain electrode of the third transistor T3 through the second node N2. The second electrode of the light emitting element ED may be connected to the common voltage line VSL. The second electrode of the light emitting element ED may receive a common voltage ELVSS (e.g., low potential voltage) from the common voltage line VSL.

The second transistor T2 may be turned on by a first gate signal GW from the first gate line GWL to electrically connect a third node N3, which is one electrode of the second capacitor Cpr, to the first node N1, which is the gate electrode of the first transistor T1. The second transistor T2 may be turned on based on the first gate signal to supply the data voltage Vd (e.g., the data voltage Vd from the data line DL) coupled by the second capacitor Cpr to the first node N1. The gate electrode of the second transistor T2 may be electrically connected to the first gate line GWL, the source electrode thereof may be electrically connected to the data line DL through the second capacitor Cpr, and the drain electrode thereof may be electrically connected to the first node N1.

The third transistor T3 may be turned on by a second gate signal GC from the second gate line GCL to electrically connect the second node N2, which is the drain electrode of the first transistor T1, to the third node N3. The gate electrode of the third transistor T3 may be electrically connected to the second gate line GCL, the source electrode thereof may be electrically connected to the third node N3, and the drain electrode thereof may be electrically connected to the second node N2. The third transistor T3 may be turned on by the second gate signal of the second gate line GCL to electrically connect the second node N2 to the third node N3. The third transistor T3 may be turned on simultaneously with the second transistor T2, thereby electrically connecting the first node N1 (the gate electrode of the first transistor T1) to the second node N2 (the drain electrode of the first transistor T1). As a result, the first transistor T1 may be configured in a diode-connected manner within the pixel circuit PC.

Each of the first transistor T1, the second transistor T2, and the third transistor T3 may include a silicon-based active layer. For example, each of the first transistor T1, the second transistor T2, and the third transistor T3 may be a p-type transistor including an active layer made of low temperature polycrystalline silicon (LTPS). Each of the first transistor T1, the second transistor T2, and the third transistor T3 may output a current flowing from the source electrode to the drain electrode when a low gate voltage is applied to the gate electrode. However, the present disclosure is not limited thereto, and each of the first transistor T1, the second transistor T2, and the third transistor T3 may be configured as an n-type transistor.

The first capacitor Cst may be connected between the first node N1, which is the gate electrode of the first transistor T1, and the initialization voltage line VIL. For example, one electrode of the first capacitor Cst may be connected to the first node N1, and the other electrode of the first capacitor Cst may be connected to the initialization voltage line VIL. The initialization voltage VINT from the initialization voltage line VIL may be coupled by the first capacitor Cst and applied to the first node N1.

The second capacitor Cpr may be connected between the data line DL and the third node N3 (e.g., the contact point between the second transistor T2 and the third transistor T3). For example, one electrode of the second capacitor Cpr may be connected to the data line DL, and the other electrode of the second capacitor Cpr may be connected to the third node N3. The data voltage Vd from the data line DL may be coupled by the second capacitor Cpr and applied to the third node N3.

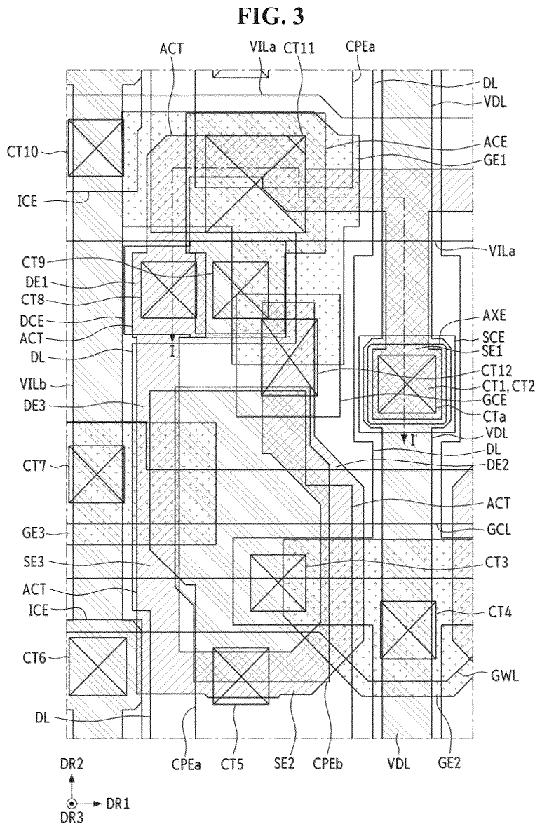

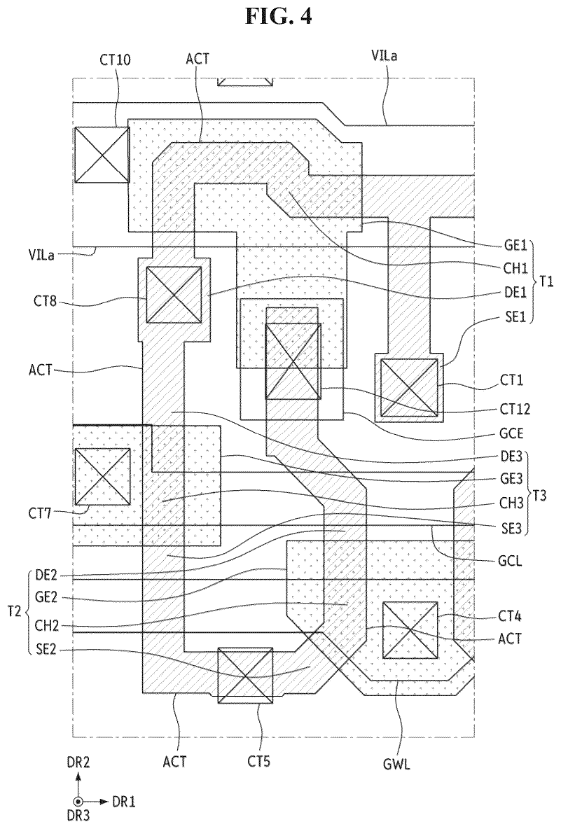

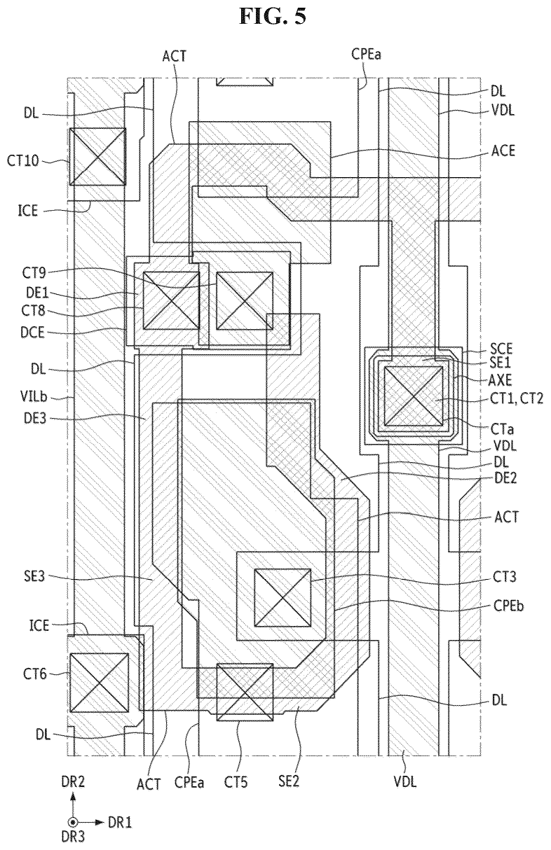

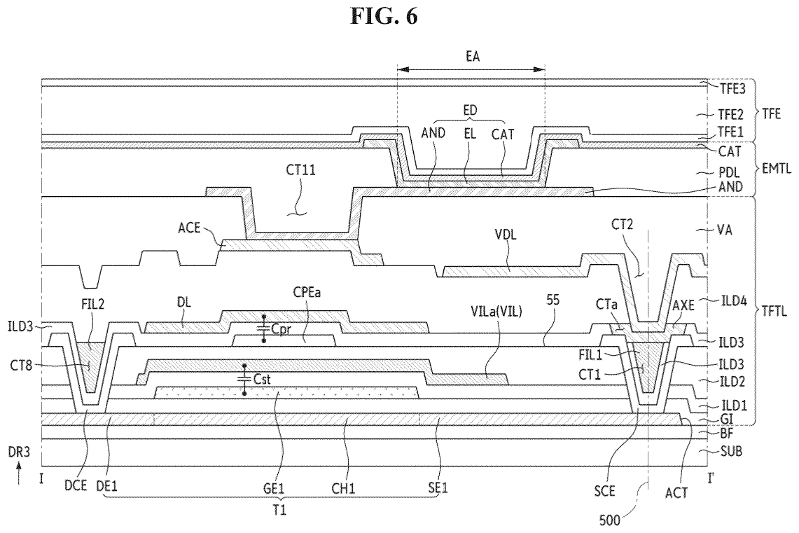

FIG. 3 is a plan view of an array structure of a pixel according to one embodiment, FIG. 4 is a plan view selectively showing a first pattern layer, a second pattern layer, and a third pattern layer among the components of FIG. 3, FIG. 5 is a diagram selectively showing the first pattern layer, a fourth pattern layer, a fifth pattern layer, and a sixth pattern layer among the components of FIG. 3, and FIG. 6 is a cross-sectional view taken along line I-I′ of FIG. 3. The first to sixth pattern layers and a seventh pattern layer to be described later may each include a conductive layer.

As illustrated in FIG. 6, the display device 10 may include a substrate SUB, a buffer film BF, a thin film transistor layer TFTL, a light emitting element layer EMTL, and an encapsulation layer ENC. The buffer film BF, the thin film transistor layer TFTL, the light emitting element layer EMTL, and the encapsulation layer ENC may be sequentially disposed on the substrate SUB along the third direction DR3.

The substrate SUB may be a rigid substrate or a flexible substrate which can be bent, folded or rolled. The substrate SUB may be formed of an insulating material such as glass, quartz, or a polymer resin. Examples of a polymer material may include polyethersulphone (PES), polyacrylate (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (TAC), cellulose acetate propionate (CAP), or a combination thereof. Alternatively, the substrate SUB may include a metal material.

As shown in FIG. 6, the buffer film BF may be disposed on the substrate SUB. The buffer film BF may be disposed on the entire surface of the substrate SUB. The buffer film BF may serve as a protective layer for the transistors T1 to T3 of the thin film transistor layer TFTL and a light emitting layer EL in the light emitting element layer EMTL, shielding them from moisture permeation through the substrate SUB, which is prone to moisture absorption.

The buffer film BF may be formed of a plurality of inorganic films that are alternately stacked. For example, the buffer film BF may be formed of multiple films in which one or more inorganic films of a silicon nitride layer, a silicon oxynitride layer, a silicon oxide layer, a titanium oxide layer and an aluminum oxide layer are alternately stacked.

The first pattern layer may be disposed on the buffer film BF. For example, the active layer ACT may be disposed on the buffer film BF. As illustrated in FIGS. 4 and 6, the active layer ACT may include a first source electrode SE1 of the first transistor T1, a first drain electrode DE1 of the first transistor T1, a first channel region CH1 of the first transistor T1, a second source electrode SE2 of the second transistor T2, a second drain electrode DE2 of the second transistor T2, a second channel region CH2 of the second transistor T2, a third source electrode SE3 of the third transistor T3, a third drain electrode DE3 of the third transistor T3, and a third channel region CH3 of the third transistor T3.

The active layer ACT1 may be an active layer made of low temperature polycrystalline silicon (LTPS).

The gate insulating film GI may be disposed on the first pattern layer. For example, as shown in FIG. 6, the gate insulating film GI may be disposed on the active layer ACT. In this case, the gate insulating film GI may be disposed on the entire surface of the substrate SUB including the active layer ACT.

The gate insulating film GI may include at least one of tetraethylorthosilicate (TEOS), silicon nitride (SiNx), or silicon oxide (SiO₂). For example, the gate insulating film GI may have a double film structure in which a silicon nitride film and a tetraethoxysilane film are sequentially stacked.

The second pattern layer may be disposed on the gate insulating film GI. For example, a first gate electrode GE1, a second gate electrode GE2, and a third gate electrode GE3 may be arranged on the gate insulating film GI. The first gate electrode GE1 may be disposed on the gate insulating film GI to overlap the first channel region CH1 of the active layer ACT. Similarly, the second gate electrode GE2 may be disposed on the gate insulating film GI to overlap the second channel region CH2 of the active layer ACT, and the third gate electrode GE3 may be disposed on the gate insulating film GI to overlap the third channel region CH3 of the active layer ACT.

The first transistor T1 may include the first gate electrode GE1, the first source electrode SE1, the first drain electrode DE1, and the first channel region CH1.

The second transistor T2 may include the second gate electrode GE2, the second source electrode SE2, the second drain electrode DE2, and the second channel region CH2.

The third transistor T3 may include the third gate electrode GE3, the third source electrode SE3, the third drain electrode DE3, and the third channel region CH3.

The second pattern layer including the first gate electrode GE1, the second gate electrode GE2, and the third gate electrode GE3 described above may include at least one of molybdenum (Mo), copper (Cu), aluminum, or titanium (Ti), and may be formed of a single layer or multiple layers. For example, the second pattern layer may be formed of a triple film including a titanium film, an aluminum film, and a titanium film disposed sequentially along the third direction DR3 on the gate insulating film GI.

A first interlayer insulating film ILD1 may be disposed on the second pattern layer. For example, the first interlayer insulating film ILD1 may be disposed on the first gate electrode GE1, the second gate electrode GE2, and the third gate electrode GE3.

The first interlayer insulating film ILD1 may include an inorganic material. For example, the first interlayer insulating film ILD1 may include the same material as the gate insulating film GI described above.

The third pattern layer may be disposed on the first interlayer insulating film ILD1. For example, a lower initialization voltage line VILa, a gate connection electrode GCE, a first gate line GWL, and a second gate line GCL may be arranged on the first interlayer insulating film ILD1.

The lower initialization voltage line VILa may extend along the first direction DR1. The lower initialization voltage line VILa may overlap the first gate electrode GE1. The first capacitor Cst may be formed in the region where the lower initialization voltage line VILa overlaps the first gate electrode GE1. The lower initialization voltage line VILa may constitute the initialization voltage line VIL together with an upper initialization voltage line VILb to be described later. For example, the initialization voltage line VIL may include the lower initialization voltage line VILa and the upper initialization voltage line VILb connected to each other.

The gate connection electrode GCE may be connected to the first gate electrode GE1 through a twelfth contact hole CT12 penetrating the first interlayer insulating film ILD1. Further, the gate connection electrode GCE may be connected to the second drain electrode DE2 through the twelfth contact hole CT12 described above. For example, a first part of the twelfth contact hole CT12 may overlap the first gate electrode GE1, and a second part of the twelfth contact hole CT12 may overlap the second drain electrode DE2. In this case, the first part of the twelfth contact hole CT12 overlapping the first gate electrode GE1 may penetrate the first interlayer insulating film ILD1, and the second part of the twelfth contact hole CT12 overlapping the second drain electrode DE2 may penetrate the first interlayer insulating film ILD1 and the gate insulating film GI.

The first gate line GWL may extend along the first direction DR1. The first gate line GWL may overlap the second gate electrode GE2. The first gate line GWL may be connected to the second gate electrode GE2 through a fourth contact hole CT4 penetrating the first interlayer insulating film ILD1.

The second gate line GCL may extend along the first direction DR1. The second gate line GCL may overlap the third gate electrode GE3. The second gate line GCL may be connected to the third gate electrode GE3 through a seventh contact hole CT7 penetrating the first interlayer insulating film ILD1.

The third pattern layer including the lower initialization voltage line VILa, the gate connection electrode GCE, the first gate line GWL, and the second gate line GCL described above may include at least one of molybdenum (Mo), copper (Cu), aluminum, or titanium (Ti), and may be formed of a single layer or multiple layers. For example, the third pattern layer may be formed of a triple film including a titanium film, an aluminum film, and a titanium film disposed sequentially along the third direction DR3 on the first interlayer insulating film ILD1.

A second interlayer insulating film ILD2 may be disposed on the third pattern layer. For example, the second interlayer insulating film ILD2 may be disposed on the lower initialization voltage line VILa, the gate connection electrode GCE, the first gate line GWL, and the second gate line GCL.

The second interlayer insulating film ILD2 may have a flat top surface 55. For example, the second interlayer insulating film ILD2 may have the flat top surface 55 formed through chemical mechanical polishing. Here, the top surface 55 of the second interlayer insulating film ILD2 may be a surface in contact with the fourth pattern layer to be described later. In other words, the top surface 55 of the second interlayer insulating film ILD2 forms an interface with the fourth pattern layer.

The second interlayer insulating film ILD2 may include an inorganic material. For example, the second interlayer insulating film ILD2 may include the same material as the gate insulating film GI described above.

The fourth pattern layer may be disposed on the second interlayer insulating film ILD2. For example, a source connection electrode SCE, a drain connection electrode DCE, a lower capacitor electrode CPEa, and an initialization connection electrode ICE may be arranged on the second interlayer insulating film ILD2.

The source connection electrode SCE may overlap the first source electrode SE1. The source connection electrode SCE may be connected to the first source electrode SE1 through a first contact hole CT1 penetrating the second interlayer insulating film ILD2, the first interlayer insulating film ILD1, and the gate insulating film GI.

The drain connection electrode DCE may overlap the first drain electrode DE1. The drain connection electrode DCE may be connected to the first drain electrode DE1 through an eighth contact hole CT8 penetrating the second interlayer insulating film ILD2, the first interlayer insulating film ILD1, and the gate insulating film GI.

The lower capacitor electrode CPEa may overlap the second source electrode SE2 and the third source electrode SE3. The lower capacitor electrode CPEa may be connected to the second source electrode SE2 and the third source electrode SE3 through a fifth contact hole CT5 penetrating the second interlayer insulating film ILD2, the first interlayer insulating film ILD1, and the gate insulating film GI.

The initialization connection electrode ICE may overlap the lower initialization voltage line VILa. The initialization connection electrode ICE may be connected to the lower initialization voltage line VILa through a tenth contact hole CT10 penetrating the second interlayer insulating film ILD2.

The fourth pattern layer including the source connection electrode SCE, the drain connection electrode DCE, the lower capacitor electrode CPEa, and the initialization connection electrode ICE described above may include at least one of molybdenum (Mo), copper (Cu), aluminum, or titanium (Ti), and may be formed of a single layer or multiple layers. For example, the fourth pattern layer may be formed of a triple film including a titanium film, an aluminum film, and a titanium film disposed sequentially along the third direction DR3 on the second interlayer insulating film ILD2.

A third interlayer insulating film ILD3 may be disposed on the fourth pattern layer. For example, the third interlayer insulating film ILD3 may be disposed on the source connection electrode SCE, the drain connection electrode DCE, the lower capacitor electrode CPEa, and the initialization connection electrode ICE.

The third interlayer insulating film ILD3 may include an inorganic material. For example, the third interlayer insulating film ILD3 may include the same material as the gate insulating film GI described above.

The fifth pattern layer may be disposed on the third interlayer insulating film ILD3. For example, the data line DL and an auxiliary connection electrode AXE may be arranged on the third interlayer insulating film ILD3.

The data line DL may overlap the lower capacitor electrode CPEa. The second capacitor Cpr may be formed in the region where the data line DL overlaps the lower capacitor electrode CPEa.

The auxiliary connection electrode AXE may overlap the first contact hole CT1 and the source connection electrode SCE. The auxiliary connection electrode AXE may be connected to the source connection electrode SCE through an auxiliary contact hole CTa penetrating the third interlayer insulating film ILD3. The auxiliary connection electrode AXE may be in contact (or direct contact) with the edge of the source connection electrode SCE.

As illustrated in FIG. 6, fillers FIL1 and FIL2 may be disposed in the first contact hole CT1 and the eighth contact hole CT8, respectively. For example, the first filler FIL1 may be positioned within the first contact hole CT1 between the auxiliary connection electrode AXE and the source connection electrode SCE, while the second filler FIL2 may be positioned within the eighth contact hole CT8 between the fourth interlayer insulating film ILD4 and the drain connection electrode DCE. In this case, the first filler FIL1 in the first contact hole CT1 may be enclosed by the auxiliary connection electrode AXE and the source connection electrode SCE. Similarly, the second filler FIL2 within the eighth contact hole CT8 may be enclosed by the fourth interlayer insulating film (ILD4) and the drain connection electrode DCE.

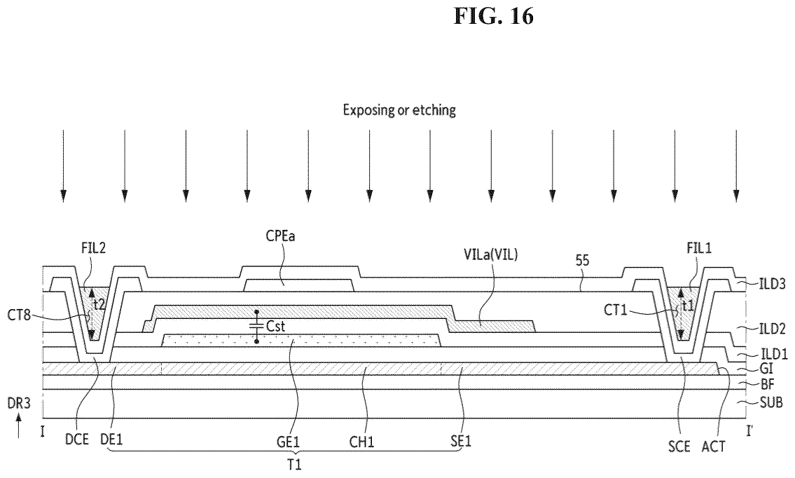

The fillers FIL1 and FIL2 may have different thicknesses for each of the contact holes. For example, the thickness (e.g., t1 in FIG. 16) of the first filler FIL1 in the first contact hole CT1 and the thickness (e.g., t2 in FIG. 16) of the second filler FIL2 in the eighth contact hole CT8 may be different from each other. More specifically, the thickness t1 of the first filler FIL1 in the first contact hole CT1 may be less than or greater than the thickness t2 of the second filler FIL2 in the eighth contact hole CT8. Here, the thicknesses t1 and t2 of the fillers FIL1 and FIL2 may be the size of the filler FIL in the third direction DR3.

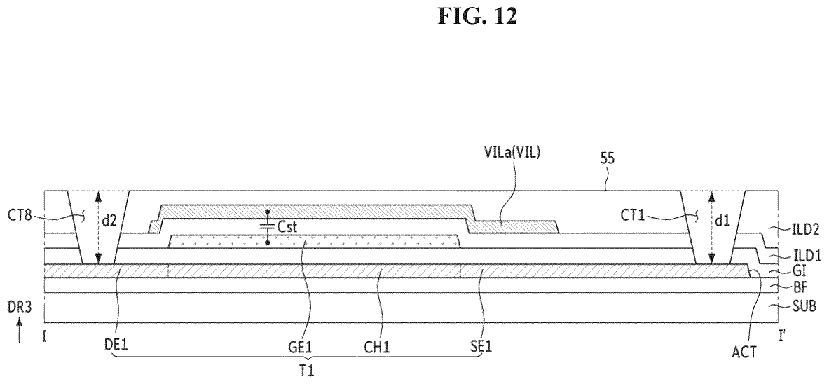

The thickness of each of the fillers FIL1 and FIL2 may have a value of 50% to 90% of the depth of the corresponding contact hole. For example, the thickness t1 of the first filler FIL1 in the first contact hole CT1 may be 50% to 90% of the depth (e.g., d1 of FIG. 12) of the first contact hole CT1, and the thickness t2 of the second filler FIL2 in the eighth contact hole CT8 may be 50% to 90% of the depth (e.g., d2 of FIG. 12) of the eighth contact hole CT8. Here, the depth d1 of the contact hole (e.g., the contact hole CT1) may be the size of the contact hole CT1 in the third direction DR3. For example, the depth d1 of the first contact hole CT1 may be defined as the distance from the interface between the active layer ACT and the source connection electrode SCE to the top surface 55 of the second interlayer insulating film ILD2.

As illustrated in FIG. 6, the third interlayer insulating film ILD3 described above may be further disposed between the source connection electrode SCE and the first filler FIL1. For example, the third interlayer insulating film ILD3 may be further disposed in the first contact hole CT1. In this case, the portion of the third interlayer insulating film ILD3 inside the first contact hole CT1 may be separated from the portion of the third interlayer insulating film ILD3 outside the first contact hole CT1, ensuring they are not connected to each other. The auxiliary connection electrode AXE and the third interlayer insulating film ILD3 in the first contact hole CT1 may surround the filler FIL in the first contact hole CT1.

The first filler FIL1 inside the first contact hole CT1 may support the auxiliary connection electrode AXE under the auxiliary connection electrode AXE. The first filler FIL1 may reduce the height difference of the auxiliary connection electrode AXE between the inside and outside of the auxiliary contact hole CTa.

Further, as illustrated in FIG. 6, the third interlayer insulating film ILD3 described above may be further disposed between the drain connection electrode DCE and the second filler FIL2. For example, the third interlayer insulating film ILD3 may be further disposed in the eighth contact hole CT8. In this case, the third interlayer insulating film ILD3 inside the eighth contact hole CT8 and the third interlayer insulating film ILD3 outside the eighth contact hole CT8 may be connected to each other. In other words, the portion of the third interlayer insulating film ILD3 inside the eighth contact hole CT8 and the portion of the third interlayer insulating film ILD3 outside the eighth contact hole CT8 may be formed as a continuous, integral structure. The second filler FIL2 in the eighth contact hole CT8 may be surrounded by the third interlayer insulating film ILD3 and the fourth interlayer insulating film ILD4.

Each of the fillers FIL1 and FIL2 may include an organic film such as acryl resin, epoxy resin, phenolic resin, polyamide resin, polyimide resin, or the like. Further, each of the fillers FIL1 and FIL2 may include an organic film having low viscosity and high heat resistance. For example, each of the fillers FIL1 and FIL2 may be made of a material including at least one of polyimide or siloxane.

The fourth interlayer insulating film ILD4 may be disposed on the fifth pattern layer. For example, the fourth interlayer insulating film ILD4 may be disposed on the data line DL and the auxiliary connection electrode AXE.

The fourth interlayer insulating film ILD4 may include an inorganic material. For example, the fourth interlayer insulating film ILD4 may include the same material as the gate insulating film GI described above.

The sixth pattern layer may be disposed on the fourth interlayer insulating film ILD4. For example, the upper initialization voltage line VILb, an upper capacitor electrode CPEb, an anode connection electrode ACE, and the driving voltage line VDL may be arranged on the fourth interlayer insulating film ILD4.

The upper initialization voltage line VILb may extend along the second direction DR2. For example, the upper initialization voltage line VILb may extend in a direction (e.g., the first direction DR1) that intersects the extension direction of the lower initialization voltage line VILa. The upper initialization voltage line VILb may overlap the lower initialization voltage line VILa and the initialization connection electrode ICE. The upper initialization voltage line VILb may be connected to the initialization connection electrode ICE through a sixth contact hole CT6 penetrating the fourth interlayer insulating film ILD4 and the third interlayer insulating film ILD3. Accordingly, the upper initialization voltage line VILb and the lower initialization voltage line VILa may be connected to each other through the initialization connection electrode ICE. As described above, the upper initialization voltage line VILb and the lower initialization voltage line VILa connected to each other may form the initialization voltage line VIL. Since the plurality of lower initialization voltage lines VILa extending along the first direction DR1 and the plurality of upper initialization voltage lines VILb extending along the second direction DR2 are connected to each other, the above-described initialization voltage line VIL may have a mesh shape in a plan view.

The upper capacitor electrode CPEb may overlap the lower capacitor electrode CPEa and the data line DL. The upper capacitor electrode CPEb may be connected to the lower capacitor electrode CPEa through the third contact hole CT3 penetrating the fourth interlayer insulating film ILD4 and the third interlayer insulating film ILD3. The second capacitor Cpr may be formed in the overlapping region between the upper capacitor electrode CPEb and the data line DL. For example, the second capacitor Cpr may be formed in both the overlapping region between the above-described data line DL and the lower capacitor electrode CPEa, and the overlapping region between the above-described data line DL and the upper capacitor electrode CPEb.

The anode connection electrode ACE may overlap the drain connection electrode DCE. The anode connection electrode ACE may be connected to the drain connection electrode DCE through a ninth contact hole CT9 penetrating the fourth interlayer insulating film ILD4 and the third interlayer insulating film ILD3.

The driving voltage line VDL may overlap at least one of the first contact hole CT1, the source connection electrode SCE, the auxiliary connection electrode AXE, or the first filler FIL1. The driving voltage line VDL may be connected to the auxiliary connection electrode AXE through a second contact hole CT2 penetrating the fourth interlayer insulating film ILD4. The driving voltage line VDL may be connected to the first source electrode SE1 through the auxiliary connection electrode AXE and the source connection electrode SCE. In this case, the driving voltage line VDL is supported by the first filler FIL1 and the auxiliary connection electrode AXE, helping to minimize the height difference of the driving voltage line VDL between the inside and outside of the second contact hole CT2. As a result, the risk of disconnection in the driving voltage line VDL may be prevented.

The second contact hole CT2 may overlap the first contact hole CT1. For example, in a plan view, the second contact hole CT2 and the first contact hole CT1 may overlap each other in the third direction DR3. For example, in the plan view illustrated in FIG. 3, the edge of the second contact hole CT2 may overlap the edge of the first contact hole CT1. Alternatively, in a plan view, the second contact hole CT2 may surround the first contact hole CT1. Meanwhile, in the plan view illustrated in FIG. 3, the auxiliary contact hole CTa may surround the first contact hole CT1 and the second contact hole CT2.

As illustrated in FIG. 6, each of the first contact hole CT1, the auxiliary contact hole CTa, and the second contact hole CT2 has a width that gradually increases along the direction (e.g., the third direction DR3) from the substrate SUB toward the encapsulation layer ENC. Consequently, the minimum width of the auxiliary contact hole CTa may be greater than the maximum width of the first contact hole CT1, and the maximum width of the second contact hole CT2 may be less than or equal to the maximum width of the auxiliary contact hole CTa. Alternatively, the minimum width of the second contact hole CT2 may be greater than or equal to the maximum width of the auxiliary contact hole CTa.

According to one embodiment, the height difference between the inside and outside of the first contact hole CT1 is minimized by the first filler FIL1. As a result, even if the contact holes (e.g., CT1 and CT2) are vertically aligned in the thickness direction of the display panel 1000 (e.g., the third direction DR3), potential connection issues, such as disconnection of the driving voltage line VDL within the contact hole, can be resolved. Therefore, the centers of the second contact hole CT2, the auxiliary contact hole CTa, and the first contact hole CT1 can be aligned along the same axis. For example, as illustrated in FIG. 6, these centers may coincide with (or overlap) an imaginary central axis 500 extending in the third direction DR3. As described above, by allowing the contact holes to overlap in the vertical direction (or thickness direction) of the display panel 1000, the overall size of the display panel 1000 in the horizontal direction (e.g., along at least one of the first direction DR1 or the second direction DR2) can be reduced. In other words, even as the number of contact holes increases, the occupied area of the pixel PX remains minimized. Therefore, according to one embodiment, increasing the number of contact holes does not compromise space efficiency, making it easier to implement a high-resolution display device.

According to one embodiment, three or more contact holes may be vertically connected in the third direction DR3. In this case, a filler may be disposed within each contact hole positioned below the uppermost contact hole in the third direction DR3. For example, when four contact holes are aligned in the third direction DR3 such that their centers coincide, they may be sequentially designated as the twenty-first contact hole, the twenty-second contact hole, the twenty-third contact hole, and the twenty-fourth contact hole, in order from the closest to the substrate. In this case, a filler may be disposed in the twenty-first, twenty-second, and twenty-third contact holes. Additionally, an auxiliary connection electrode may be placed between vertically adjacent contact holes. For instance, a first auxiliary connection electrode may be positioned in a first auxiliary contact hole between the twenty-first and twenty-second contact holes, a second auxiliary connection electrode may be positioned in a second auxiliary contact hole between the twenty-second and twenty-third contact holes, and a third auxiliary connection electrode may be positioned in a third auxiliary contact hole between the twenty-third and twenty-fourth contact holes.

A planarization film VA may be disposed on the sixth pattern layer. For example, the planarization film VA may be disposed on the upper initialization voltage line VILb, the upper capacitor electrode CPEb, the anode connection electrode ACE, and the driving voltage line VDL.

The planarization film VA may include an organic material. For example, the planarization film VA may include an organic film such as acryl resin, epoxy resin, phenolic resin, polyamide resin, polyimide resin and the like.

The seventh pattern layer may be disposed on the planarization film VA. For example, as shown in FIG. 6, the light emitting element layer EMTL including the seventh pattern layer may be disposed on the planarization film VA. For example, as illustrated in FIG. 6, an anode electrode AND may be disposed as the seventh pattern layer on the planarization film VA. The anode electrode AND may be connected to the anode connection electrode ACE through an eleventh contact hole CT11 penetrating the planarization film VA.

The aforementioned light emitting element layer EMTL may further include the light emitting element ED and a pixel defining film PDL in addition to the aforementioned seventh pattern layer.

The light emitting element ED may include the anode electrode AND, the light emitting layer EL and a cathode electrode CAT. The emission area EA represents a region where the anode electrode AND, the light emitting layer EL and the cathode electrode CAT are stacked sequentially and holes from the anode electrode AND and electrons from the cathode electrode CAT are coupled to each other in the light emitting layer EL to emit light.

In a top emission structure that emits light toward the cathode electrode CAT with respect to the light emitting layer EL, the anode electrode AND may be formed of a single layer of molybdenum (Mo), titanium (Ti), copper (Cu), or aluminum (Al), or may be formed to have a stacked structure (Ti/Al/Ti) of aluminum and titanium, a stacked structure (ITO/Al/ITO) of aluminum and ITO, an APC alloy, or a stacked structure (ITO/APC/ITO) of APC alloy and ITO to increase the reflectivity. The APC alloy is an alloy of silver (Ag), palladium (Pd) and copper (Cu).

The pixel defining film PDL may serve to define the emission areas EA of the pixels PX. To this end, the pixel defining film PDL may be disposed to expose a partial area of the anode electrode AND on the planarization film VA. The pixel defining film PDL may cover an edge of the anode electrode AND. The pixel defining film PDL may be disposed in the eleventh contact hole CT11 penetrating the planarization film VA. Accordingly, the eleventh contact hole CT11 penetrating the planarization film VA may be filled by the pixel defining film PDL. The pixel defining film PDL may be formed of an organic layer such as acryl resin, epoxy resin, phenolic resin, polyamide resin, polyimide resin and the like.

A spacer may be disposed on the pixel defining film PDL. The spacer may serve to support a mask during a process of manufacturing the light emitting layer EL. The spacer may be formed of an organic layer such as acryl resin, epoxy resin, phenolic resin, polyamide resin, polyimide resin and the like.

The light emitting layer EL may be disposed on the anode electrode AND. The light emitting layer EL may include an organic material to emit light in a predetermined color. For example, the light emitting layer EL may include a hole transporting layer, an organic material layer, and an electron transporting layer. The organic material layer may include a host and a dopant. The organic material layer may include a material that emits predetermined light, and may be formed using a phosphorescent material or a fluorescent material.

The aforementioned light emitting element ED may be provided for each pixel PX. For example, when the plurality of pixels PX include a first pixel, a second pixel, and a third pixel providing different colors, the first pixel may include a first light emitting element, the second pixel may include a second light emitting element, and the third pixel may include a third light emitting element. The first light emitting element, the second light emitting element, and the third light emitting element may provide light of different colors. For example, the first light emitting element may emit light of a first color, the second light emitting element may emit light of a second color, and the third light emitting element may emit light of a third color.

For example, the organic material layer of the first light emitting layer of the first emission area emitting the light of the first color may be a phosphorescent material including a host material including carbazole biphenyl (CBP) or mCP (1,3-bis(carbazol-9-yl), and a dopant including at least one selected from the group consisting of PIQIr(acac)(bis(1-phenylisoquinoline)acetylacetonate iridium), PQIr(acac)(bis(1-phenylquinoline)acetylacetonate iridium), PQIr(tris(1-phenylquinoline)iridium)) and PtOEP (octaethylporphyrin platinum). Alternatively, the organic material layer of the first light emitting layer of the first emission area may be a fluorescent material including PBD:Eu(DBM)3(Phen) or Perylene, but the present disclosure is not limited thereto.

The organic material layer of the second light emitting layer of the second emission area emitting the light of the second color may be a phosphorescent material including a host material including CBP or mCP, and a dopant material including Ir(ppy)3(fac tris(2-phenylpyridine)iridium. Alternatively, the organic material layer of the second light emitting layer of the second emission area emitting the light of the second color may be a fluorescent material including tris(8-hydroxyquinolino)aluminum (Alq3), but the present disclosure is not limited thereto.

The organic material layer of the light emitting layer of the third emission area emitting the light of the third color may be a phosphorescent material including a host material including CBP or mCP, and a dopant material including (4,6-F2ppy)2Irpic or L2BD111, but the present disclosure is not limited thereto.

The cathode electrode CAT may be disposed on the first, second, and third light emitting layers (e.g., EL). The cathode electrode CAT may be disposed to cover the first, second, and third light emitting layers (e.g., EL). The cathode electrode CAT may be a common layer commonly disposed in the first to third light emitting layers. A capping layer may be disposed on the cathode electrode CAT.

In the top emission structure, the cathode electrode CAT may be formed of a transparent conductive material (TCO) such as ITO or IZO capable of transmitting light or a semi-transmissive conductive material such as magnesium (Mg), silver (Ag), or an alloy of magnesium (Mg) and silver (Ag). When the cathode electrode CAT is formed of a semi-transmissive conductive material, the light output efficiency can be increased due to a micro-cavity effect.

The encapsulation layer ENC may be formed on the light emitting element layer EMTL. The encapsulation layer ENC may include at least one inorganic film TFE1 and TFE3 to prevent oxygen or moisture from permeating into the light emitting element layer EMTL. In addition, the encapsulation layer ENC may include at least one organic film to protect the light emitting element layer EMTL from foreign substances such as dust. For example, the encapsulation layer ENC may include a first encapsulation inorganic film TFE1, an encapsulation organic film TFE2, and a second encapsulation inorganic film TFE3.

The first encapsulation inorganic film TFE1 may be disposed on the cathode electrode CAT, the encapsulation organic film TFE2 may be disposed on the first encapsulation inorganic film TFE1, and the second encapsulation inorganic film TFE3 may be disposed on the encapsulation organic film TFE2. The first encapsulation inorganic film TFE1 and the second encapsulation inorganic film TFE3 may be formed of multiple films in which one or more inorganic films of a silicon nitride layer, a silicon oxynitride layer, a silicon oxide layer, a titanium oxide layer and an aluminum oxide layer are alternately stacked. The encapsulation organic film TFE2 may be an organic film such as acryl resin, epoxy resin, phenolic resin, polyamide resin, polyimide resin or the like.

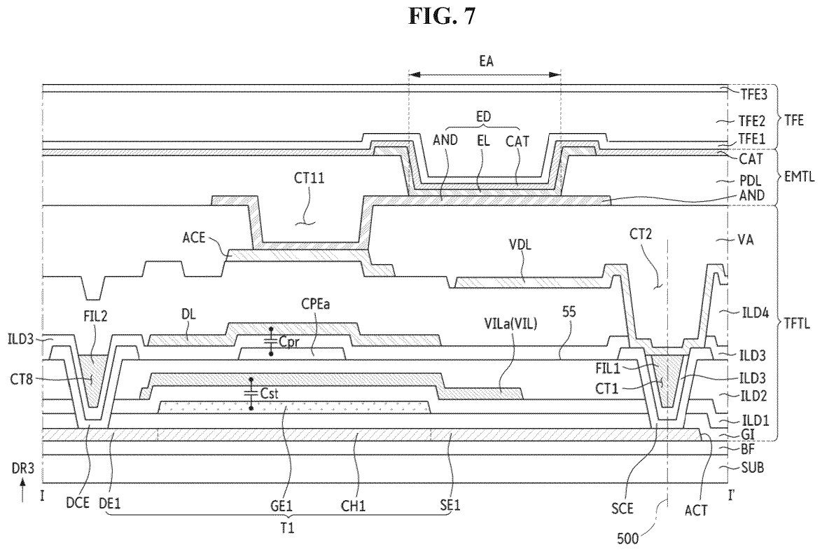

FIG. 7 is a cross-sectional view of a display device according to another embodiment. For example, FIG. 7 may be a cross-sectional view of another embodiment of a display device, which is taken along line I-I′ of FIG. 3.

The display device of FIG. 7 differs from the display device of FIG. 6 in that the source connection electrode SCE is directly connected to the driving voltage line VDL. The following description will mainly focus on this difference.

As illustrated in FIG. 7, the driving voltage line VDL may be directly connected to, in contact with, or in direct contact with the source connection electrode SCE without the need for the auxiliary connection electrode AXE. For example, the driving voltage line VDL may be directly connected to the source connection electrode SCE through the second contact hole CT2 penetrating the fourth interlayer insulating film ILD4 and the third interlayer insulating film ILD3.

The driving voltage line VDL may be connected to the first filler FIL1 in the first contact hole CT1. The first filler FIL1 may be surrounded by the driving voltage line VDL and the third interlayer insulating film ILD3 in the first contact hole CT1. The first filler FIL1 may support the driving voltage line VDL under the driving voltage line VDL. The first filler FIL1 may reduce the height difference of the driving voltage line VDL between the inside and outside of the second contact hole CT2. As a result, the risk of disconnection in the driving voltage line VDL can be prevented.

In FIG. 7, the second contact hole CT2 may be greater than the first contact hole CT1. For example, in a plan view, the second contact hole CT2 may surround the first contact hole CT1.

As illustrated in FIG. 7, the width of each of the first contact hole CT1 and the second contact hole CT2 gradually increase along the third direction DR3 from the substrate SUB toward the encapsulation layer ENC. As a result, the minimum width of the second contact hole CT2 may be greater than the maximum width of the first contact hole CT1.

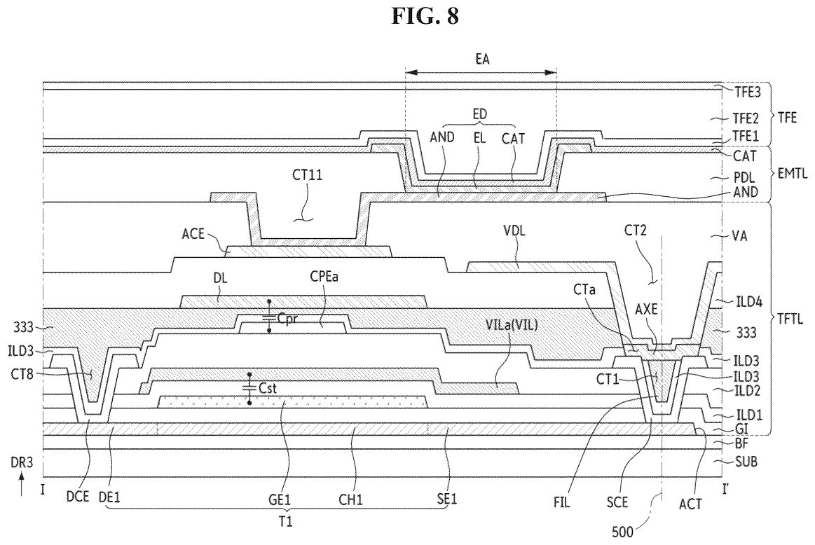

FIG. 8 is a cross-sectional view of a display device according to another embodiment. For example, FIG. 8 may be a cross-sectional view of another embodiment of a display device, which is taken along line I-I′ of FIG. 3.

The display device of FIG. 8 is different from the display device of FIG. 6 described above in that it further includes an auxiliary planarization film 333. Additionally, unlike the display device in FIG. 6, the second interlayer insulating film ILD2 is not planarized. The following description will primarily focus on these differences.

As illustrated in FIG. 8, the auxiliary planarization film 333 may be disposed between the third interlayer insulating film ILD3 and the fourth interlayer insulating film ILD4. The second interlayer insulating film ILD2 and the third interlayer insulating film ILD3 may be planarized by the auxiliary planarization film 333. In other words, when the auxiliary planarization film 333 is added, a planarization process (e.g., chemical mechanical polishing) for the second interlayer insulating film ILD2 may be omitted. Therefore, the top surface of the second interlayer insulating film ILD2 may have a height difference.

The auxiliary planarization film 333 may include an organic material. For example, the auxiliary planarization film 333 may include an organic film such as acryl resin, epoxy resin, phenolic resin, polyamide resin, polyimide resin and the like. Further, the auxiliary planarization film 333 may include an organic film having low viscosity and high heat resistance. For example, the auxiliary planarization film 333 may be made of a material including at least one of polyimide or siloxane. In this case, the auxiliary planarization film 333 and the filler FIL may include the same material.

In FIG. 8, the driving voltage line VDL may be connected to the auxiliary connection electrode AXE through the second contact hole CT2 penetrating the fourth interlayer insulating film ILD4 and the auxiliary planarization film 333.

As illustrated in FIG. 8, the widths of the first contact hole CT1, the auxiliary contact hole CTa, and the second contact hole CT2 gradually increase along the third direction DR3 from the substrate SUB toward the encapsulation layer ENC. As a result, the minimum width of the auxiliary contact hole CTa may be greater than the maximum width of the first contact hole CT1, and the minimum width of the second contact hole CT2 may be greater than or equal to the maximum width of the auxiliary contact hole CTa. Alternatively, the maximum width of the second contact hole CT2 may be less than or equal to the maximum width of the auxiliary contact hole CTa.

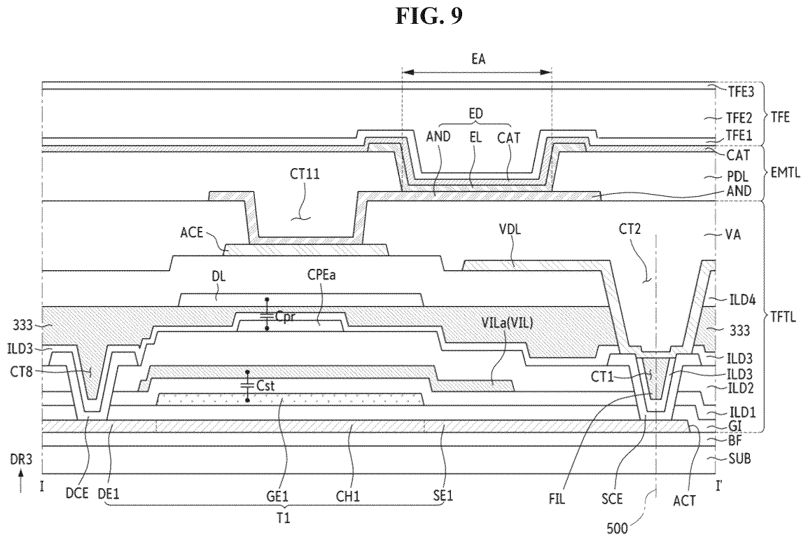

FIG. 9 is a cross-sectional view of a display device according to another embodiment. For example, FIG. 9 may be a cross-sectional view of another embodiment of a display device, which is taken along line I-I′ of FIG. 3.

The display device of FIG. 9 differs from the display device of FIG. 8 in that the source connection electrode SCE is directly connected to the driving voltage line VDL. The following description will mainly focus on this difference.

As illustrated in FIG. 9, the driving voltage line VDL may be directly connected to, in contact with, or in direct contact with the source connection electrode SCE without the auxiliary connection electrode AXE. For example, the driving voltage line VDL may be directly connected to the source connection electrode SCE through the second contact hole CT2 penetrating the fourth interlayer insulating film ILD4, the auxiliary planarization film 333, and the third interlayer insulating film ILD3.

The driving voltage line VDL may be connected to the filler FIL in the first contact hole CT1. The filler FIL may be surrounded by the driving voltage line VDL and the third interlayer insulating film ILD3 in the first contact hole CT1. The filler FIL may support the driving voltage line VDL under the driving voltage line VDL. The filler FIL may reduce the height difference of the driving voltage line VDL between the inside and outside of the second contact hole CT2. As a result, the risk of disconnection in the driving voltage line VDL can be prevented.

In FIG. 9, the second contact hole CT2 may be greater than the first contact hole CT1. For example, in a plan view, the second contact hole CT2 may surround the first contact hole CT1.

As illustrated in FIG. 9, the widths of both the first contact hole CT1 and the second contact hole CT2 gradually increase along the third direction DR3 from the substrate SUB toward the encapsulation layer ENC. Consequently, the minimum width of the second contact hole CT2 may be greater than the maximum width of the first contact hole CT1.

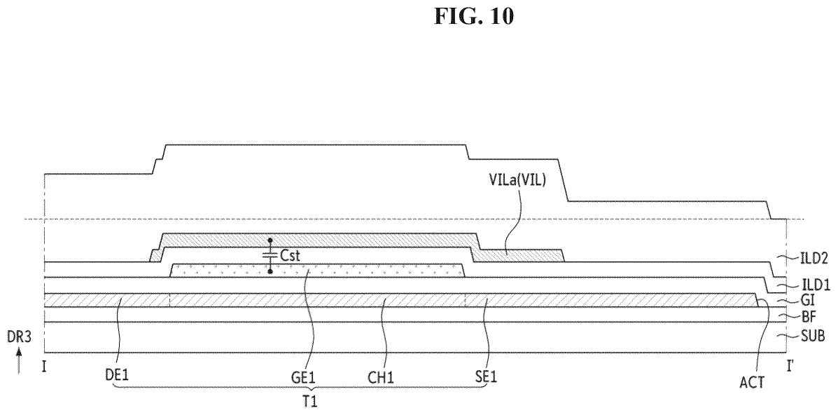

FIGS. 10, 11, 12, 13, 14, 15, 16, 17, 18, 19, 20, 21, and 22 are process cross-sectional views illustrating a method for fabricating a display device according to one embodiment. For example, FIGS. 10 to 22 may be process cross-sectional views for describing the method for fabricating the display device of FIG. 6.

First, as illustrated in FIG. 10, the buffer film BF may be formed on the substrate SUB, the first pattern layer (e.g., the active layer ACT) may then be formed on the buffer film BF, the gate insulating film GI may then be formed on the first pattern layer, the second pattern layer (e.g., the first gate electrode GE1) may then be formed on the gate insulating film GI, the first interlayer insulating film ILD1 may then be formed on the second pattern layer, the third pattern layer (e.g., the lower initialization voltage line VILa) may then be formed on the first interlayer insulating film ILD1, and the second interlayer insulating film ILD2 may then be formed on the third pattern layer. In this case, the second interlayer insulating film ILD2 may have a curvature along the stepped portion of the lower structure. In other words, the top surface of the second interlayer insulating film ILD2 may have a height difference.

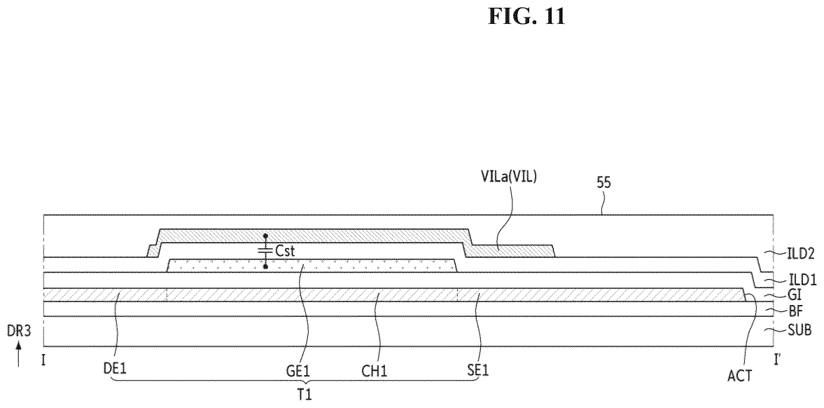

Next, a planarization process may be performed to planarize the second interlayer insulating film ILD2 of FIG. 10. For example, in the second interlayer insulating film ILD2 having a height difference, the second interlayer insulating film ILD2 may be removed with respect to the lowest stepped portion. More specifically, the entire second interlayer insulating film ILD2 located above the lowest stepped portion (e.g., the portion indicated by the horizontal dotted line in FIG. 10) of the second interlayer insulating film ILD2 may be removed by chemical and mechanical polishing. Accordingly, as shown in FIG. 11, the top surface 55 of the second interlayer insulating film ILD2 may be planarized.

Thereafter, as illustrated in FIG. 12, the eighth contact hole CT8 exposing the first drain electrode DE1 and the first contact hole CT1 exposing the first source electrode SE1 may be formed to penetrate the second interlayer insulating film ILD2, the first interlayer insulating film ILD1, and the gate insulating film GI.

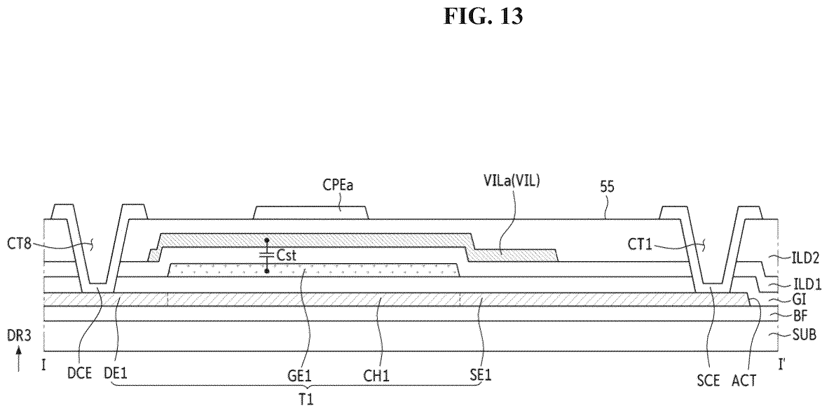

Next, as illustrated in FIG. 13, the fourth pattern layer (e.g., the drain connection electrode DCE, the lower capacitor electrode CPEa, and the source connection electrode SCE) may be formed on the second interlayer insulating film ILD2. In this case, the drain connection electrode DCE may be connected to the first drain electrode DE1 through the eighth contact hole CT8, and the source connection electrode SCE may be connected to the first source electrode SE1 through the first contact hole CT1.

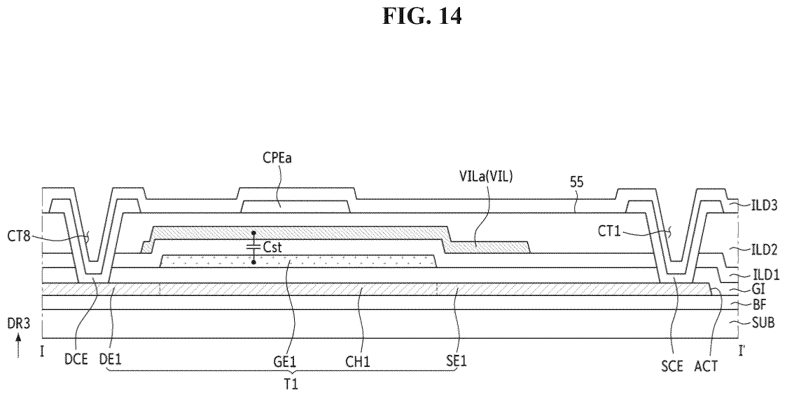

Thereafter, as illustrated in FIG. 14, the third interlayer insulating film ILD3 may be formed on the fourth pattern layer (e.g., the drain connection electrode DCE, the lower capacitor electrode CPEa, and the source connection electrode SCE). In this case, a part of the third interlayer insulating film ILD3 may be disposed in each of the eighth contact hole CT8 and the first contact hole CT1.

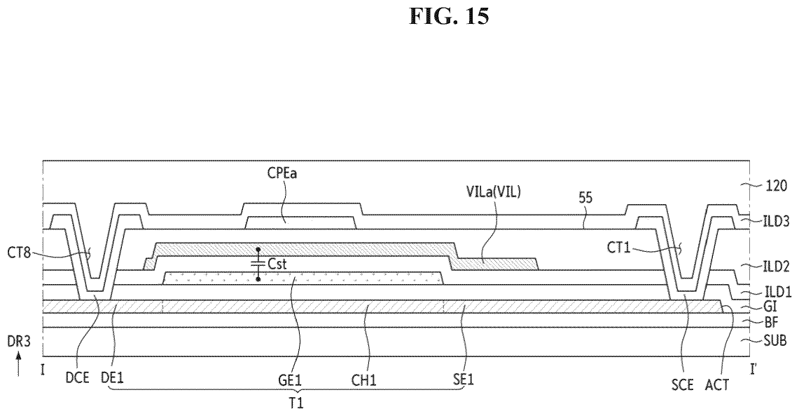

Next, as illustrated in FIG. 15, an organic film 120 may be formed on the third interlayer insulating film ILD3. In this case, the organic film 120 may be disposed in the eighth contact hole CT8 and the first contact hole CT1. In other words, the organic film 120 may be filled in the eighth contact hole CT8 and the first contact hole CT1. In order to minimize the thickness of the organic film 120 (e.g., the thickness of the organic film 120 outside the contact hole) and minimize damage during subsequent processes (e.g., the etching process of the organic film), an organic film with low viscosity and high heat resistance may be used for the organic film 120. For example, the organic film 120 may be made of a material including at least one of polyimide or siloxane.

Next, as shown in FIG. 16, the organic film 120 outside the contact holes may be removed. In this case, the organic film 120 may be removed by an exposure process or an etching process without requiring a separate mask. For example, an exposure process and a development process for the entire surface of the organic film may be performed, or an etching process (e.g., dry etching or ashing process) for the entire surface of the organic film may be performed. Specifically, a photosensitive organic film may be selectively removed by a full-surface exposure, development, heat treatment, and descum process, and a non-photosensitive organic film may be selectively removed by a dry etching process. Then, due to the height difference between the inside and the outside of the contact holes CT8 and CT1, the organic film 120 may be easily removed from the areas outside the contact holes CT8 and CT1, while remaining inside each of the contact holes CT8 and CT1 without being removed. Accordingly, the organic film 120 may be selectively removed only outside the contact holes CT8 and CT1 without using a mask. In other words, the organic film 120 remains only in the contact holes CT8 and CT1, thereby forming the fillers FIL2 and FIL1. For example, a residual film (e.g., the second filler FIL2 and the first filler FIL1) of the organic film 120 may be formed in the eighth contact hole CT8 and the first contact hole CT1, respectively. In this way, the eighth contact hole CT8 and the first contact hole CT1 are filled with the fillers FIL2 and FIL1, respectively, minimizing the height difference between the inside and outside of each of the eighth contact hole CT8 and the first contact hole CT1.

As described above, since the organic film 120 is removed by full-surface exposure and development (or full-surface etching) without a mask, the fillers FIL1 and FIL2 formed from the organic film 120 may have different thicknesses for each of the contact holes. For example, the thickness t1 of the first filler FIL1 in the first contact hole CT1 and the thickness t2 of the second filler FIL2 in the eighth contact hole CT8 may be different from each other. More specifically, the thickness t1 of the first filler FIL1 in the first contact hole CT1 may be less than or greater than the thickness t2 of the second filler FIL2 in the eighth contact hole CT8. Here, the thicknesses t1 and t2 of the fillers FIL1 and FIL2 may be the size of the fillers FIL1 and FIL2 in the third direction DR3.

The thicknesses of the fillers FIL1 and FIL2 may have a value of 50% to 90% of the depth of the contact hole. For example, the thickness t1 of the first filler FIL1 in the first contact hole CT1 may be 50% to 90% of the depth d1 of the first contact hole CT1, and the thickness t2 of the second filler FIL2 in the eighth contact hole CT8 may be 50% to 90% of the depth d2 of the eighth contact hole CT8. Here, the depth d1 of the contact hole (e.g., the contact hole CT1) may be the size of the contact hole CT1 in the third direction DR3. For example, the depth d1 of the first contact hole CT1 may be defined as the distance from the interface between the active layer ACT and the source connection electrode SCE to the top surface 55 of the second interlayer insulating film ILD.

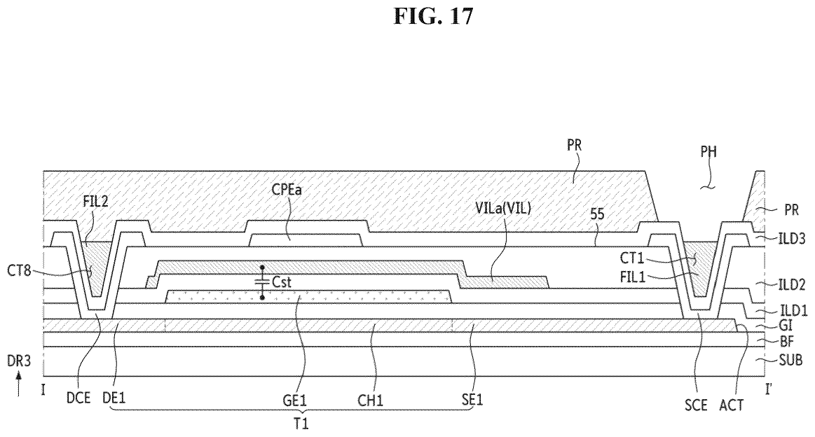

Thereafter, as illustrated in FIG. 17, a photoresist pattern PR may be formed on the first filler FIL1, the second filler FIL2, and the third interlayer insulating film ILD3. The photoresist pattern PR may have a pattern hole PH overlapping the first contact hole CT1, the first filler FIL1 in the first contact hole CT1, and the source connection electrode SCE.

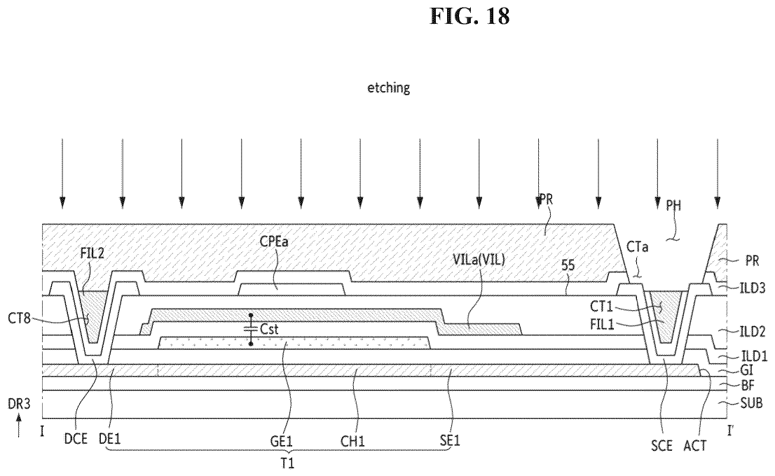

Next, as illustrated in FIG. 18, an etching process using the photoresist pattern PR as a mask may be performed. Accordingly, the third interlayer insulating film ILD3 exposed through the pattern hole PH of the photoresist pattern PR may be removed, thereby exposing the first filler FIL1 and the source connection electrode SCE (e.g., the edge of the source connection electrode SCE on the second interlayer insulating film ILD2) thereunder. For example, the third interlayer insulating film ILD3 may be removed in the region overlapping the pattern hole PH, thereby forming the auxiliary contact hole CTa penetrating the third interlayer insulating film ILD3. In other words, due to an etching process using the photoresist pattern PR as a mask, the third interlayer insulating film ILD3 may have the auxiliary contact hole CTa exposing the first filler FIL1 in the first contact hole CT1 and the source connection electrode SCE (e.g., the edge of the source connection electrode SCE on the second interlayer insulating film ILD2). In this case, due to the presence of the auxiliary contact hole CTa, the third interlayer insulating film ILD3 may be separated, preventing the portions inside and outside the first contact hole CT1 from being connected to each other.

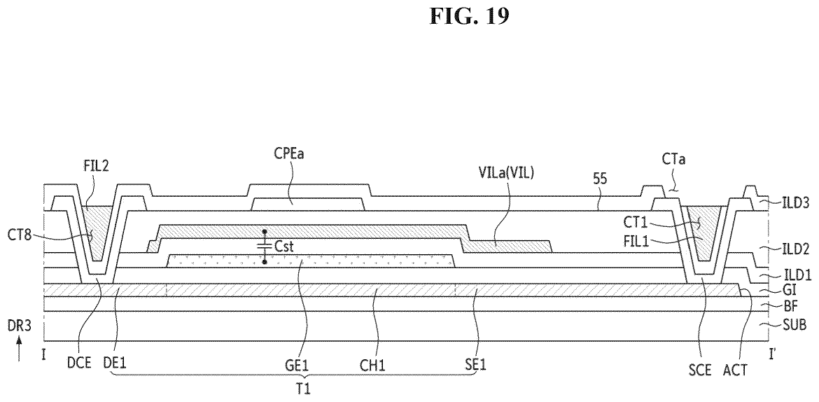

Subsequently, as illustrated in FIG. 19, the photoresist pattern PR may be removed. The photoresist pattern PR may be removed by, e.g., a strip solution.

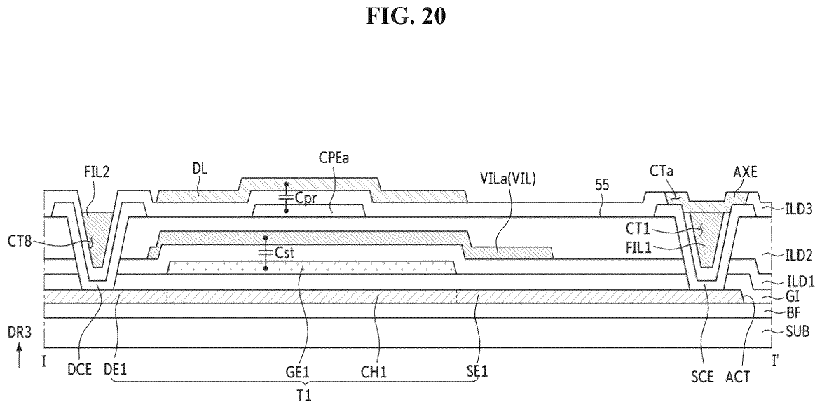

Thereafter, as illustrated in FIG. 20, the fifth pattern layer (e.g., the data line DL and the auxiliary connection electrode AXE) may be formed on the third interlayer insulating film ILD3. In this case, the auxiliary connection electrode AXE may be formed in the auxiliary contact hole CTa. The auxiliary connection electrode AXE may be in contact with, in direct contact with, or directly connected to the source connection electrode SCE through the auxiliary contact hole CTa. For example, the auxiliary connection electrode AXE may be in contact with the edge of the source connection electrode SCE exposed to the outside of the first contact hole CT1. Further, the auxiliary connection electrode AXE may be in contact with, in direct contact with, or directly connected to the first filler FIL1 in the first contact hole CT1.

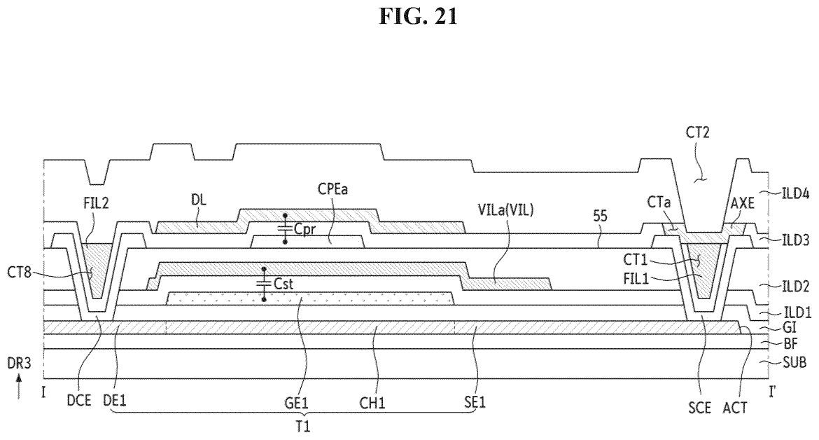

Next, as illustrated in FIG. 21, the fourth interlayer insulating film ILD4 having the second contact hole CT2 may be formed on the fifth pattern layer (e.g., the data line DL and the auxiliary connection electrode AXE). The second contact hole CT2 of the fourth interlayer insulating film ILD4 may expose the auxiliary connection electrode AXE. The second contact hole CT2 may overlap the first contact hole CT1, the first filler FIL1 in the first contact hole CT1, the source connection electrode SCE, and the first source electrode SE1.

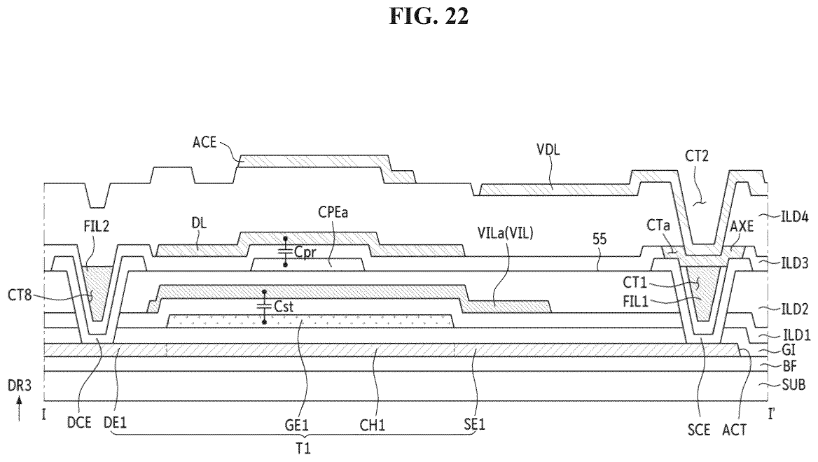

Thereafter, as illustrated in FIG. 22, the sixth pattern layer (e.g., the anode connection electrode ACE and the driving voltage line VDL) may be formed on the fourth interlayer insulating film ILD4. The driving voltage line VDL may be in contact with, in direct contact with, or directly connected to the auxiliary connection electrode AXE through the second contact hole CT2.

Next, the planarization film VA, the light emitting element layer EMTL, and the encapsulation layer ENC may be arranged on the sixth pattern layer, thereby fabricating the display device illustrated in FIG. 6.

The method for fabricating the display device shown in FIG. 7 is different from that in FIG. 20 in that the auxiliary connection electrode AXE is not formed. Accordingly, the source connection electrode SCE in FIG. 7 may be directly connected to the driving voltage line VDL without the auxiliary connection electrode AXE.

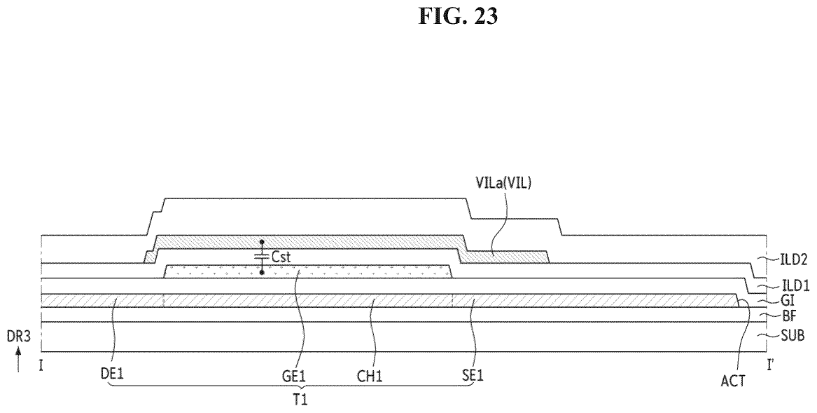

FIGS. 23, 24, 25, 26, 27, 28, 29, 30, 31, and 32 are process cross-sectional views illustrating a method for fabricating a display device according to another embodiment. For example, FIGS. 23 to 32 may be process cross-sectional views for describing the method for fabricating the display device of FIG. 8.

First, as illustrated in FIG. 23, the buffer film BF may be formed on the substrate SUB, the first pattern layer (e.g., the active layer) may then be formed on the buffer film BF, the gate insulating film GI may then be formed on the first pattern layer, the second pattern layer (e.g., the first gate electrode GE1) may then be formed on the gate insulating film GI, the first interlayer insulating film ILD1 may then be formed on the second pattern layer, the third pattern layer (e.g., the lower initialization voltage line VILa) may then be formed on the first interlayer insulating film ILD1, and the second interlayer insulating film ILD2 may then be formed on the third pattern layer. In this case, the second interlayer insulating film ILD2 may have a curvature along the stepped portion of the lower structure.

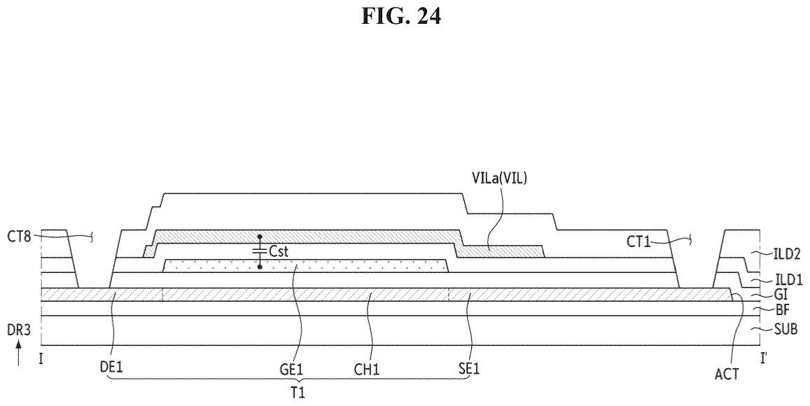

Thereafter, as illustrated in FIG. 24, the eighth contact hole CT8 exposing the first drain electrode DE1 and the first contact hole CT1 exposing the first source electrode SE1 may be formed to penetrate the second interlayer insulating film ILD2, the first interlayer insulating film ILD1, and the gate insulating film GI.

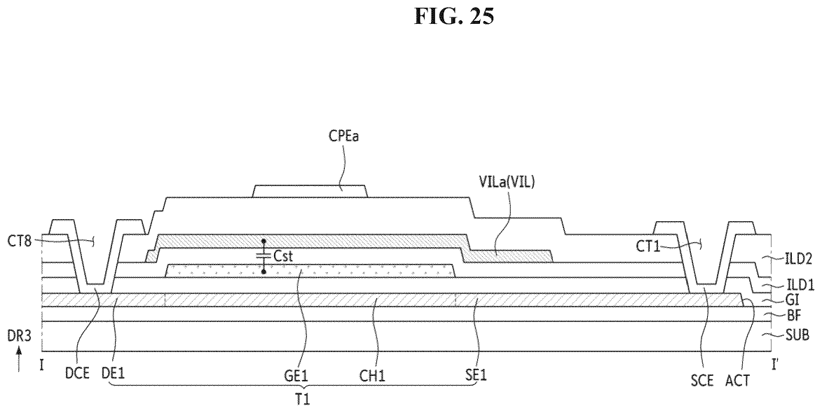

Next, as illustrated in FIG. 25, the fourth pattern layer (e.g., the drain connection electrode DCE, the lower capacitor electrode CPEa, and the source connection electrode SCE) may be formed on the second interlayer insulating film ILD2. In this case, the drain connection electrode DCE may be connected to the first drain electrode DE1 through the eighth contact hole CT8, and the source connection electrode SCE may be connected to the first source electrode SE1 through the first contact hole CT1.

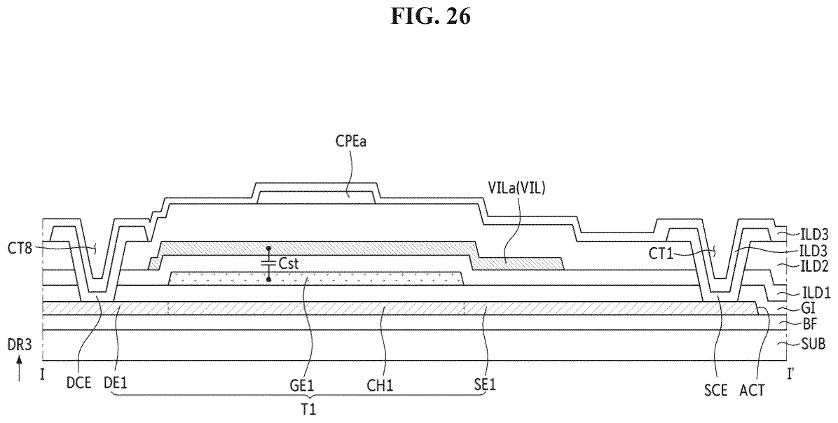

Thereafter, as illustrated in FIG. 26, the third interlayer insulating film ILD3 may be formed on the fourth pattern layer (e.g., the drain connection electrode DCE, the lower capacitor electrode CPEa, and the source connection electrode SCE). In this case, a part of the third interlayer insulating film ILD3 may be disposed in each of the eighth contact hole CT8 and the first contact hole CT1.

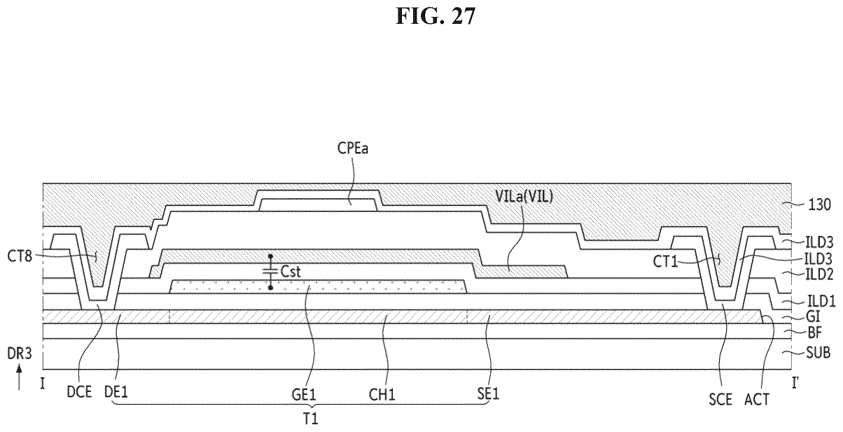

Next, as illustrated in FIG. 27, an organic film 130 may be formed on the third interlayer insulating film ILD3. In this case, the organic film 130 may be disposed in the eighth contact hole CT8 and the first contact hole CT1. In other words, the organic film 130 may be filled in the eighth contact hole CT8 and the first contact hole CT1.

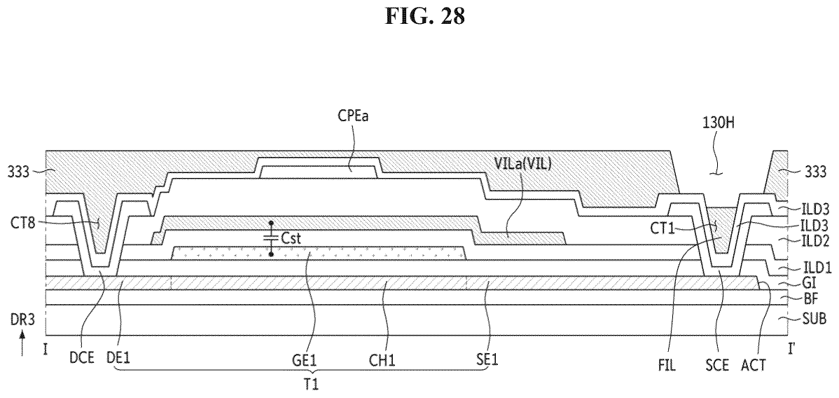

Next, as illustrated in FIG. 28, the organic film 130 may be patterned by an exposure and development process, thereby forming the auxiliary planarization film 333 and the filler FIL. The auxiliary planarization film 333 may have a pattern hole 130H overlapping the first contact hole CT1, the filler FIL in the first contact hole CT1, and the source connection electrode SCE. Meanwhile, during the patterning process of the organic film 130, the height difference between the inside and outside of the first contact hole CT1 may cause the organic film 130 to be easily removed from the areas outside the first contact hole CT1 while remaining inside the first contact hole CT1 without being removed. Consequently, a residual film (e.g., the filler FIL) of the organic film 130 may be formed within the first contact hole CT1. In this way, the first contact hole CT1 is filled with the filler FIL, minimizing the height difference between the inside and outside of the first contact hole CT1.

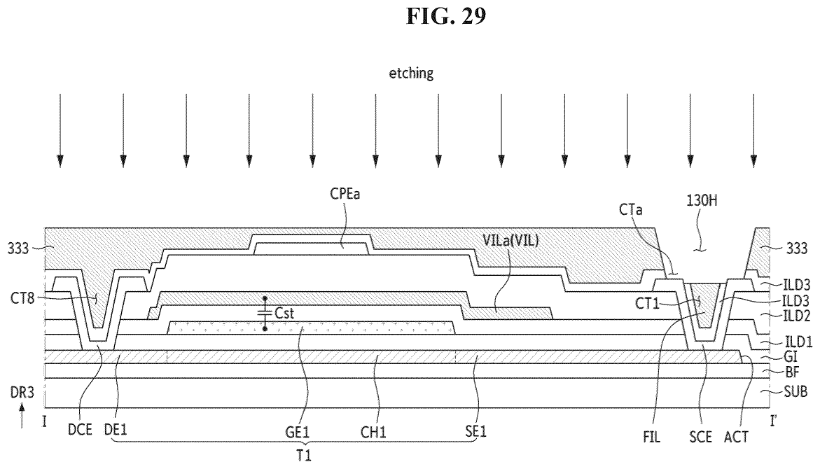

Thereafter, as illustrated in FIG. 29, an etching process using the auxiliary planarization film 333 as a mask may be performed. Accordingly, the third interlayer insulating film ILD3 exposed through the pattern hole 130H of the auxiliary planarization film 333 may be removed, thereby exposing the filler FIL and the source connection electrode SCE (e.g., the edge of the source connection electrode SCE on the second interlayer insulating film ILD2) thereunder. For example, the third interlayer insulating film ILD3 may be removed in the region overlapping the pattern hole 130H, thereby forming the auxiliary contact hole CTa penetrating the third interlayer insulating film ILD3. In other words, due to an etching process using the auxiliary planarization film 333 as a mask, the third interlayer insulating film ILD3 may have the auxiliary contact hole CTa exposing the filler FIL in the first contact hole CT1 and the source connection electrode SCE (e.g., the edge of the source connection electrode SCE on the second interlayer insulating film ILD2). In this case, the presence of the auxiliary contact hole CTa may cause the third interlayer insulating film ILD3 to be separated, preventing the portions inside and outside the first contact hole CT1 from being connected to each other.

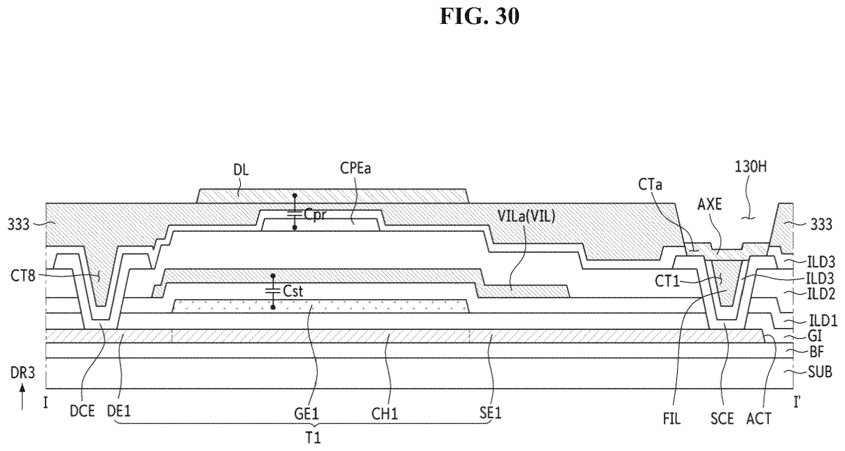

Thereafter, as illustrated in FIG. 30, the fifth pattern layer (e.g., the data line DL and the auxiliary connection electrode AXE) may be formed on the third interlayer insulating film ILD3. In this case, the auxiliary connection electrode AXE may be formed in the auxiliary contact hole CTa. The auxiliary connection electrode AXE may be in contact with, in direct contact with, or directly connected to the source connection electrode SCE through the auxiliary contact hole CTa. For example, the auxiliary connection electrode AXE may be in contact with the edge of the source connection electrode SCE exposed to the outside of the first contact hole CT1. Further, the auxiliary connection electrode AXE may be in contact with, in direct contact with, or directly connected to the filler FIL in the first contact hole CT1.

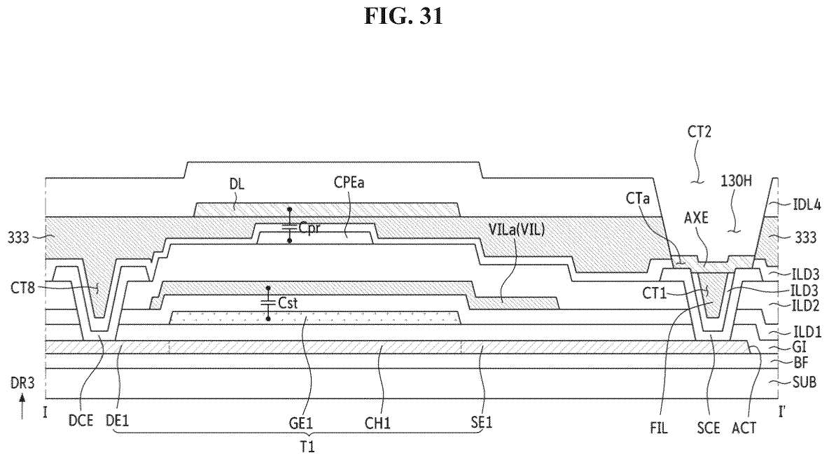

Next, as illustrated in FIG. 31, the fourth interlayer insulating film ILD4 having the second contact hole CT2 may be formed on the fifth pattern layer (e.g., the data line DL and the auxiliary connection electrode AXE). The second contact hole CT2 of the fourth interlayer insulating film ILD4 may expose the auxiliary connection electrode AXE. The second contact hole CT2 may overlap the first contact hole CT1, the filler FIL in the first contact hole CT1, the source connection electrode SCE, and the first source electrode SE1. Here, the second contact hole CT2 may include the pattern hole 130H of the auxiliary planarization film 333 described above.

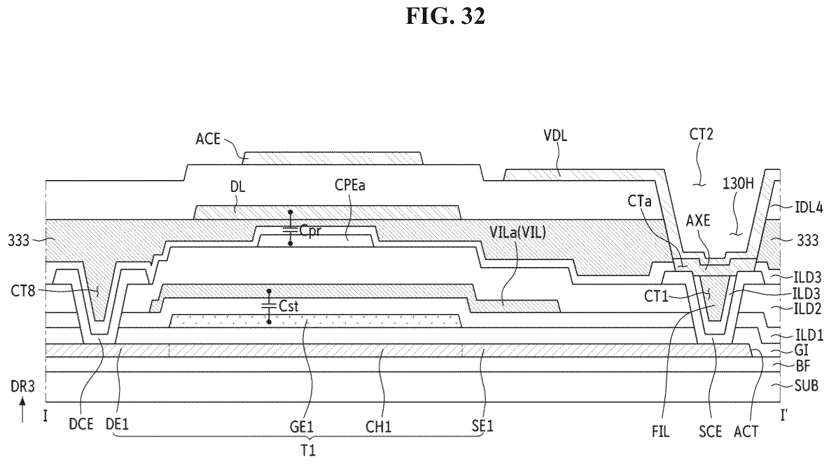

Thereafter, as illustrated in FIG. 32, the sixth pattern layer (e.g., the anode connection electrode ACE and the driving voltage line VDL) may be formed on the fourth interlayer insulating film ILD4. The driving voltage line VDL may be in contact with (or in direct contact with, or directly connected to) the auxiliary connection electrode AXE through the second contact hole CT2.

Next, the planarization film VA, the light emitting element layer EMTL, and the encapsulation layer ENC may be arranged on the sixth pattern layer, thereby fabricating the display device illustrated in FIG. 8.

Meanwhile, the method for fabricating the display device illustrated in FIG. 9 is different from that in FIG. 30 in that the auxiliary connection electrode AXE is not formed. Accordingly, the source connection electrode SCE in FIG. 9 may be directly connected to the driving voltage line VDL without the auxiliary connection electrode AXE.

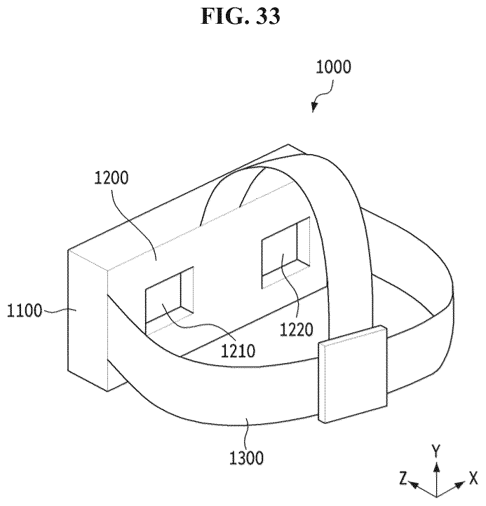

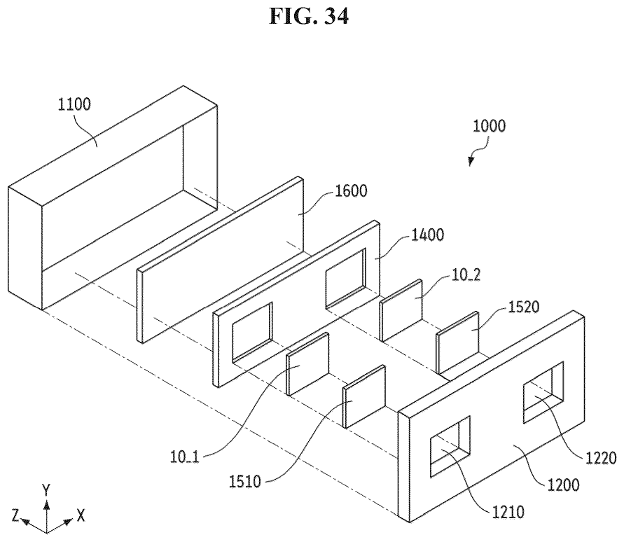

FIG. 33 is a perspective view illustrating a head mounted display according to one embodiment. FIG. 34 is an exploded perspective view illustrating an example of the head mounted display of FIG. 33.

Referring to FIGS. 33 and 34, a head mounted display 1000 according to one embodiment includes a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 provides an image to the user's left eye, and the second display device 10_2 provides an image to the user's right eye. Since each of the first display device 10_1 and the second display device 10_2 is substantially the same as the display device described in conjunction with FIGS. 1 to 32, description of the first display device 10_1 and the second display device 10_2 will be omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first display device 10_1 and the control circuit board 1600 and between the second display device 10_2 and the control circuit board 1600. The middle frame 1400 serves to support and fix the first display device 10_1, the second display device 10_2, and the control circuit board 1600.

The control circuit board 1600 may be disposed between the middle frame 1400 and the display device housing 1100. The control circuit board 1600 may be connected to the first display device 10_1 and the second display device 10_2 through the connector. The control circuit board 1600 may convert an image source inputted from the outside into the digital video data DATA, and transmit the digital video data DATA to the first display device 10_1 and the second display device 10_2 through the connector.

The control circuit board 1600 may transmit the digital video data DATA corresponding to a left-eye image optimized for the user's left eye to the first display device 10_1, and may transmit the digital video data DATA corresponding to a right-eye image optimized for the user's right eye to the second display device 10_2. Alternatively, the control circuit board 1600 may transmit the same digital video data DATA to the first display device 10_1 and the second display device 10_2.

The display device housing 1100 serves to accommodate the first display device 10_1, the second display device 10_2, the middle frame 1400, the first optical member 1510, the second optical member 1520, and the control circuit board 1600. The housing cover 1200 is disposed to cover one open surface of the display device housing 1100. The housing cover 1200 may include the first eyepiece 1210 at which the user's left eye is located and the second eyepiece 1220 at which the user's right eye is located. Although it is illustrated in FIGS. 33 and 34 that the first eyepiece 1210 and the second eyepiece 1220 are disposed separately, the embodiment of the present disclosure is not limited thereto. The first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

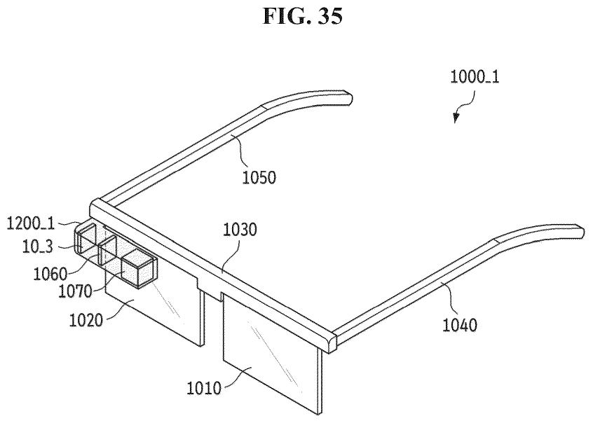

The head mounted band 1300 serves to secure the display device housing 1100 to the user's head such that the first eyepiece 1210 and the second eyepiece 1220 of the housing cover 1200 remain located on the user's left and right eyes, respectively. When the display device housing 1200 is implemented to be lightweight and compact, the head mounted display 1000 may be provided with an eyeglass frame as shown in FIG. 35 instead of the head mounted band 1300.

FIG. 35 is a perspective view illustrating a head mounted display according to one embodiment.

Referring to FIG. 35, a head mounted display 1000_1 according to one embodiment may be an eyeglasses-type display device in which a display device housing 1200_1 is implemented in a lightweight and compact manner. The head mounted display 1000_1 according to one embodiment may include a display device 10_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 10_3, the optical member 1060, and the optical path changing member 1070. The image displayed on the display device 10_3 may be magnified by the optical member 1060, and may be provided to the user's right eye through the right eye lens 1020 after the optical path thereof is changed by the optical path changing member 1070. As a result, the user may view an augmented reality image, through the right eye, in which a virtual image displayed on the display device 10_3 and a real image seen through the right eye lens 1020 are combined.

FIG. 35 illustrates that the display device housing 1200_1 is disposed at the right end of the support frame 1030, but the embodiment of the present disclosure is not limited thereto. For example, the display device housing 1200_1 may be disposed at the left end of the support frame 1030, and in this case, the image of the display device 10_3 may be provided to the user's left eye. Alternatively, the display device housing 1200_1 may be disposed at both the left and right ends of the support frame 1030, and in this case, the user may view the image displayed on the display device 10_3 through both the left and right eyes.

The display device according to this embodiment can be applied to various electronic devices. In one embodiment, an electronic device includes the aforementioned display device and may further incorporate additional modules or components that provide supplementary functions beyond the display device.

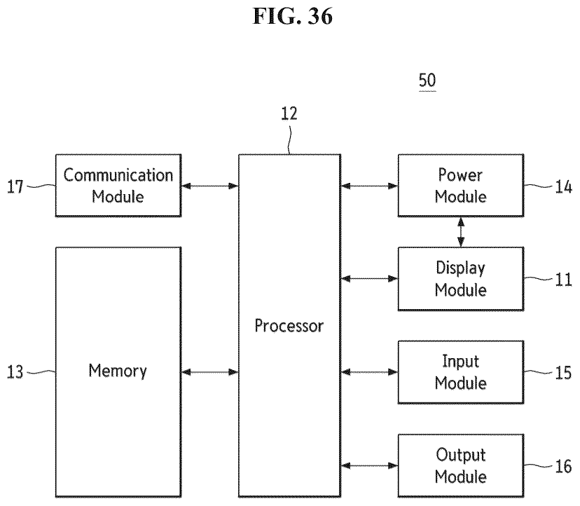

FIG. 36 is a block diagram of an electronic device according to one embodiment. Referring to FIG. 36, the electronic device 50 according to one embodiment may include a display module, a processor 12, a memory 13, and a power module 14. The electronic device 50 may further include an input module 14, a non-image output module 15 and/or a communication module 16.

The electronic device 50 may output various information in the form of images through the display module 11. When the processor 12 executes an application stored in the memory 13, image information provided by the application may be provided to the user through the display module 11. The power module 14 may include a power supply module such as a power adapter or a battery device, and a power conversion module that converts the power supplied by the power supply module to generate power required for the operation of the electronic device 50. The input module 14 may provide input information to the processor 12 and/or the display module 11. The non-image output module 15 may receive information other than images transmitted from the processor 12, such as sound, haptics, and light, and provide the information to the user. The communication module 16 is a module that is responsible for transmitting and receiving information between the electronic device 50 and an external device, and may include a receiving unit and a transmitting unit.

At least one component of the electronic device 50 described above may be integrated into the display device according to the embodiments described earlier. Additionally, some individual modules functionally included within a single module may be incorporated into the display device, while others may be provided separately from the display device. For example, the display device includes a display module 1100, and the processor 12, memory 13, and power module 14 may be provided in the form of other devices within the electronic device 11 other than the display device.

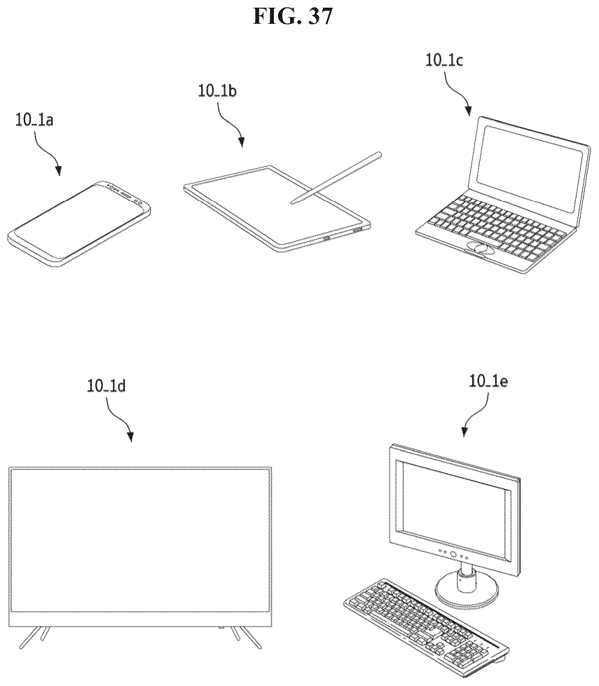

FIGS. 37, 38 and 39 are schematic diagrams of electronic devices according to various embodiments. FIGS. 37 to 39 illustrate examples of various electronic devices to which the display device according to the embodiments is applied.

FIG. 37 illustrates a smartphone 10_1a, a tablet PC 10_1b, a laptop 10_1c, a TV 10_1d, and a desk monitor 10_1e as examples of electronic devices.

In addition to the display module 11, the smartphone 10_1a may include an input module such as a touch sensor and a communication module. The smartphone 10_1a may process information received through the communication module or other input modules and display the information through the display module of the display device.

In the case of tablet PCs 10_1b, laptops 10_1c, TVs 10_1d, and desk monitors 10_1e, they also include display modules and input modules similar to smartphones 10_1, and may additionally include communication modules in some cases.

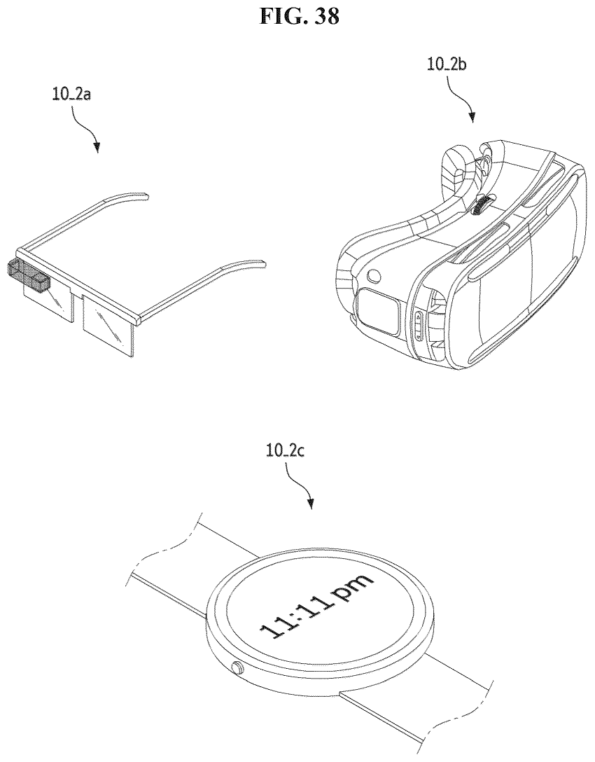

FIG. 38 shows an example of an electronic device including a display module being applied to a wearable electronic device. The wearable electronic device may be a smart glasses 10_2a, a head-mounted display 10_2b, a smart watch 10_2c, etc.

The smart glasses 10_2a and the head-mounted display 10_2b may include a display module that emits a display image and a reflector that reflects the emitted display screen and provides it to the user's eyes, thereby providing a virtual reality or augmented reality screen to the user.

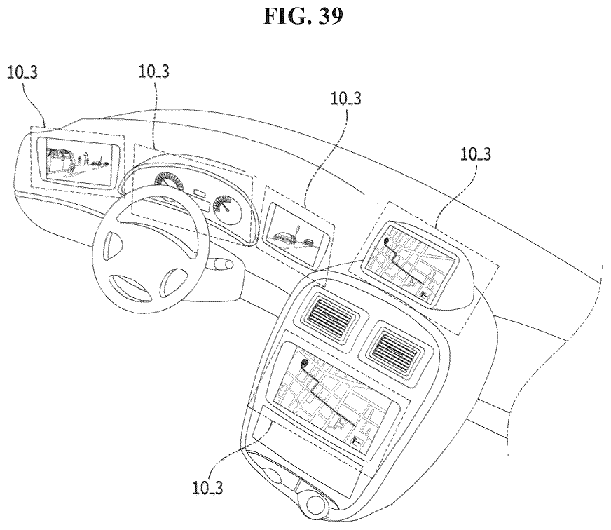

The smart watch 10_2c includes a biometric sensor as an input device, and may provide biometric information recognized by the biometric sensor to the user through the display module. FIG. 39 illustrates a case where an electronic device including a display module is applied to a vehicle. For example, the electronic device 10_3 may be applied to a dashboard, center fascia, etc. of a vehicle, or may be applied to a CID (Center Information Display) placed on a dashboard of a vehicle, or a room mirror display replacing a side mirror.

It will be understood by those of ordinary skill in the art that the present disclosure may be implemented in various forms without departing from its technical spirit or essential features. Accordingly, the exemplary embodiments described above are intended for illustration rather than limitation. The scope of the present disclosure is defined by the claims, not by the foregoing detailed description, and encompasses all modifications, variations, and equivalents as interpreted from the claims.

What is claimed is:

1. A display device comprising:
a substrate;
a light emitting element layer on the substrate;
a first conductive layer between the substrate and the light emitting element layer;
a first insulating film on the first conductive layer and having a first contact hole;
a second insulating film between the first insulating film and the light emitting element layer and having a second contact hole overlapping the first contact hole;
a second conductive layer on the first insulating film and connected to the first conductive layer through the first contact hole;
a first filler in the first contact hole; and
a third insulating film within the first contact hole and positioned between the second conductive layer and the first filler.

2. The display device of claim 1, wherein the third insulating film includes an inorganic material.

3. The display device of claim 1, wherein the first filler includes an organic material.

4. The display device of claim 1, further comprising:
a third conductive layer between the substrate and the light emitting element layer;
a third contact hole penetrating the first insulating film to expose the third conductive layer;
a fourth conductive layer on the first insulating film and connected to the third conductive layer through the third contact hole; and
a second filler in the third contact hole.

5. The display device of claim 4, wherein the third insulating film is further positioned within the third contact hole between the third conductive layer and the second filler.

6. The display device of claim 5, wherein the third insulating film is further disposed on the first insulating film.

7. The display device of claim 6, wherein the third insulating film in the first contact hole is separated from the third insulating film on the first insulating film and the third insulating film in the third contact hole.

8. The display device of claim 7, wherein the third insulating film in the third contact hole and the third insulating film on the first insulating film are connected to each other.

9. The display device of claim 4, wherein the first filler and the second filler have different thicknesses.

10. The display device of claim 1, further comprising a fifth conductive layer connected to the second conductive layer through the second contact hole on the second insulating film.

11. The display device of claim 10, wherein the fifth conductive layer is directly connected to the second conductive layer.

12. The display device of claim 10, further comprising an auxiliary connection electrode between the second conductive layer and the fifth conductive layer.

13. The display device of claim 12, wherein the third insulating film is further disposed on the first insulating film,
the third insulating film on the first insulating film has an auxiliary contact hole positioned between the first contact hole and the second contact hole,
the auxiliary connection electrode extends through the auxiliary contact hole connecting the second conductive layer to the first filler, and
the auxiliary connection electrode is connected to the fifth conductive layer through the second contact hole.

14. The display device of claim 13, wherein a center of the first contact hole, a center of the auxiliary contact hole, and a center of the second contact hole coincide with each other.

15. The display device of claim 1, wherein a top surface of the first insulating film is planarized.

16. The display device of claim 1, wherein a center of the first contact hole and a center of the second contact hole coincide with each other.

17. The display device of claim 1, wherein the third insulating film is further disposed on the first insulating film,
the display device further comprising an auxiliary planarization film between the third insulating film and the second insulating film.

18. The display device of claim 17, further comprising a fifth conductive layer connected to the second conductive layer through the second contact hole on the second insulating film,
wherein the second contact hole extends through the second insulating film and the auxiliary planarization film.

19. A method for fabricating a display device, comprising:
depositing a first conductive layer on a substrate;
forming a first insulating film on the first conductive layer;
planarizing the first insulating film;
creating a first contact hole through the first insulating film to expose the first conductive layer;
depositing a second conductive layer on the first insulating film, connected to the first conductive layer through the first contact hole;
forming a second insulating film in the first contact hole and on the first insulating film and the second conductive layer;
depositing an organic film in the first contact hole and on the second insulating film;
removing the organic film from the second insulating film without a mask to form a filler within the first contact hole;
exposing the second conductive layer;
creating a second contact hole overlapping the first contact hole on the second conductive layer;
depositing a third conductive layer, connected to the second conductive layer through the second contact hole; and
forming a light emitting element layer on the third conductive layer.

20. An electronic device comprising:
a display device including a screen;
wherein the display device comprises:
a substrate;
a light emitting element layer on the substrate;
a first conductive layer between the substrate and the light emitting element layer;
a first insulating film on the first conductive layer and having a first contact hole;
a second insulating film between the first insulating film and the light emitting element layer and having a second contact hole overlapping the first contact hole;
a second conductive layer on the first insulating film and connected to the first conductive layer through the first contact hole;
a first filler in the first contact hole; and
a third insulating film in the first contact hole and positioned between the second conductive layer and the first filler.
